(19) United States
(12) Patent Application Publication
(10) Pub. No.: US 2026/0068382 A1
(43) Pub. Date: Mar. 5, 2026

(54) DISPLAY DEVICE

(71) Applicant: LG Display Co., Ltd., Seoul (KR)

(72) Inventors: Wonrae KIM, Paju-si (KR); ByungGwan HYUN, Seoul (KR); Jiyoon CHOI, Cheongju-si (KR)

(73) Assignee: LG Display Co., Ltd., Seoul (KR)

(21) Appl. No.: 19/278,497

(22) Filed: Jul. 23, 2025

(30) Foreign Application Priority Data
Sep. 3, 2024 (KR) 10-2024-00119351

(51) Int. Cl. H10H 29/37; H10H 29/34

(52) U.S. Cl. CPC H10H 29/37; H10H 29/345

(57) ABSTRACT

A display device can include a substrate defining an active area and a non-active area extending from the active area. A plurality of sub pixels can be disposed in the active area. The display device can further include a planarization layer disposed on the substrate, and a light emitting diode disposed on the planarization layer in each of the plurality of sub pixels. The light emitting diode includes a first electrode, an emission layer, and a second electrode which can be sequentially laminated. The planarization layer can include a base portion and a protrusion portion protruding from the base portion. The first electrode can be disposed on the base portion to enclose a side surface of the protrusion portion. The display device can have improved light extraction efficiency.

### CROSS-REFERENCE TO RELATED APPLICATIONS

This application claims priority to Korean Patent Application No. 10-2024-0119351 filed on Sep. 3, 2024, in the Korean Intellectual Property Office, the entire disclosure of which is hereby expressly incorporated by reference into the present application.

### BACKGROUND

### Field

The present disclosure relates to a display device, and more particularly, to a display device with improved light extraction efficiency.

### Discussion of the Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied. Various efforts are being continued to improve the light extraction efficiency of the display device.

For example, light emitted from an emission layer of a light emitting diode of the display device passes through various components of the display device to be released to the outside of the display device. However, some of the light emitted from the emission layer is trapped in the display device without being released to the outside of the display device so that the light extraction efficiency of the display device is reduced to cause light loss. The light loss can cause increase of power consumption of the display device and reduction in the lifespan of the light emitting diode of the display device.

### SUMMARY OF THE DISCLOSURE

An object to be achieved by the present disclosure is to provide a display device with improved light extraction efficiency.

Another object to be achieved by the present disclosure is to provide a display device with an improved front luminance.

Still another object to be achieved by the present disclosure is to provide a display device which is driven at a low power while implementing high luminance.

Objects of the present disclosure are not limited to the above-mentioned objects, and other objects, which are not mentioned above, can be clearly understood by those skilled in the art from the following descriptions.

A display device according to an aspect of the present disclosure can comprise a substrate defining an active area and a non-active area extending from the active area, wherein a plurality of sub pixels can be disposed in the active area; a planarization layer disposed on the substrate; and a light emitting diode disposed on the planarization layer in each of the plurality of sub pixels, the light emitting diode including a first electrode, an emission layer, and a second electrode which can be sequentially laminated. The planarization layer can include a base portion and a protrusion portion protruding from the base portion, and the first electrode can be disposed on the base portion to enclose a side surface of the protrusion portion.

Other detailed matters of the example embodiments of the present disclosure are included in the detailed description and the drawings.

According to aspects of the present disclosure, the first electrode is disposed so as to enclose a side surface of the protrusion portion of the planarization layer to improve the light extraction efficiency.

According to aspects of the present disclosure, a first bank including a black material is disposed between the plurality of sub pixels to suppress color mixture between adjacent sub pixels, thereby improving a reflective visibility.

According to aspects of the present disclosure, the first bank is disposed so as to expose a part of the first electrode disposed on the side surface of the protrusion portion so that the light directed to the side surface is not absorbed by the first bank, but is reflected by the first electrode.

According to aspects of the present disclosure, the protrusion portion is asymmetrically formed to increase a width of the first electrode disposed on the side surface of the protrusion portion while maintaining an area of the emission layer, thereby improving the reflection efficiency.

According to aspects of the present disclosure, a second bank which is a pixel definition film is asymmetrically formed to increase a width of the first electrode which is disposed to be spaced apart from the emission layer while maintaining an area of the emission layer, thereby improving the reflection efficiency.

According to aspects of the present disclosure, a width of a part of the first electrode exposed by the first bank which is disposed to be adjacent to the non-active area is formed to be relatively larger to efficiently reflect light directed to the non-active area to the active area.

According to aspects of the present disclosure, the light extraction efficiency is improved to implement a high luminance to drive the display device at a low power in terms of reduction of power consumption.

The effects according to the present disclosure are not limited to the contents exemplified above, and further various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of a display device according to an example embodiment of the present disclosure;

FIG. 2A is an enlarged plan view of an area A of FIG. 1;

FIG. 2B is an enlarged plan view of an area B of FIG. 1;

FIG. 3A is a cross-sectional view of a display device taken along a line IIIa-IIIa′ of FIG. 2A;

FIG. 3B is a cross-sectional view of a display device taken along a line IIIb-IIIb′ of FIG. 2B;

FIG. 4 is a cross-sectional view of the same area as FIG. 3B of a display device according to another example embodiment of the present disclosure;

FIG. 5 is a cross-sectional view of the same area as FIG. 3B of a display device according to still another example embodiment of the present disclosure;

FIG. 6 is an enlarged plan view of the same area as FIG. 2B of a display device according to still another example embodiment of the present disclosure;

FIG. 7 is a cross-sectional view taken along a line VII-VII′ of FIG. 6;

FIG. 8 is a cross-sectional view of the same area as FIG. 7 of a display device according to still another example embodiment of the present disclosure; and

FIG. 9 is a cross-sectional view of the same area as FIG. 7 of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may” and vice versa.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiments of the present disclosure are operatively coupled and configured.

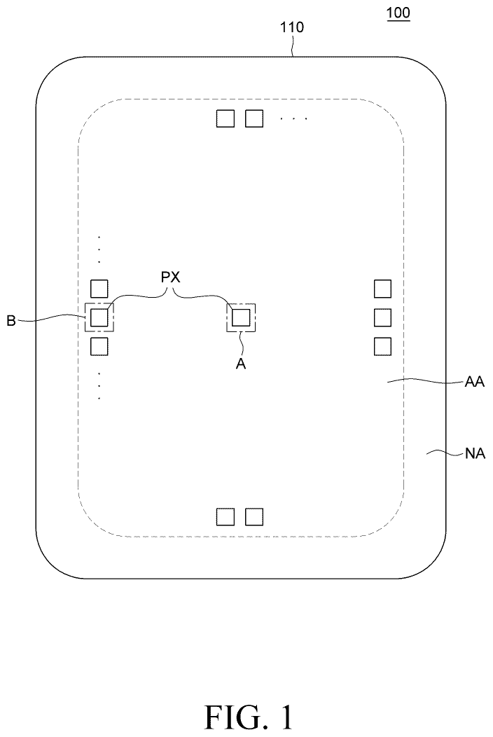

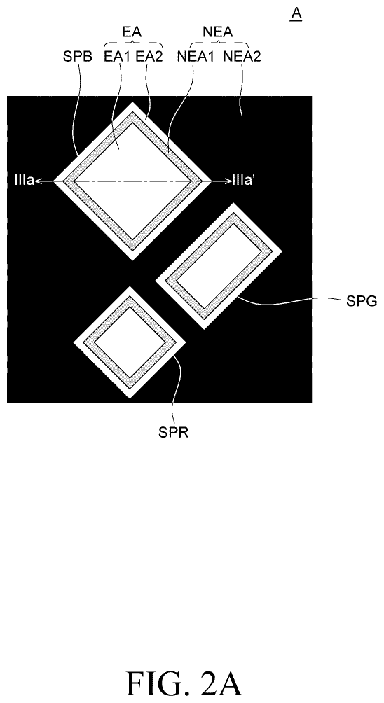

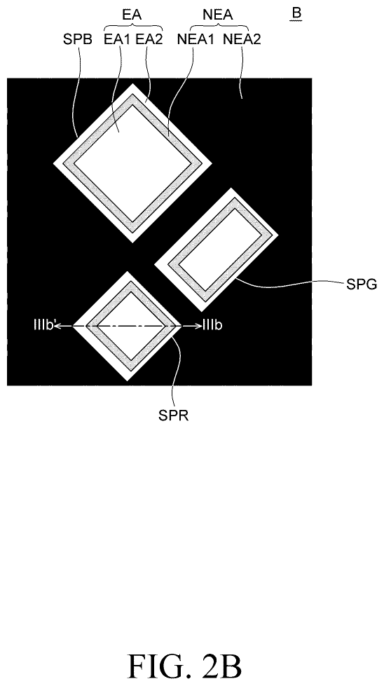

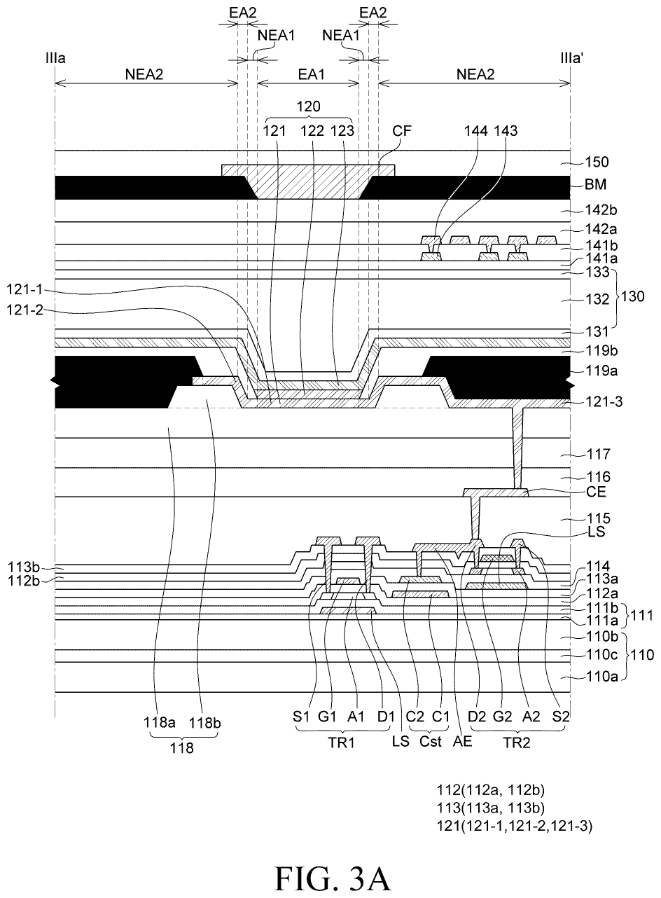

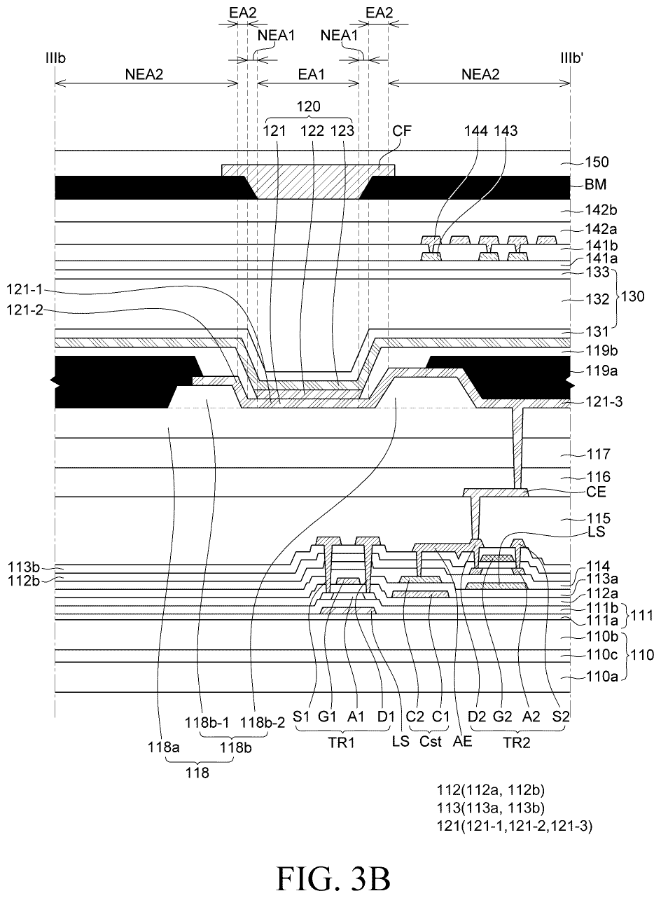

FIG. 1 is a schematic plan view of a display device according to an example embodiment of the present disclosure. FIG. 2A is an enlarged plan view of an area A of FIG. 1. FIG. 2B is an enlarged plan view of an area B of FIG. 1. FIG. 3A is a cross-sectional view of a display device taken along a line IIIa-IIIa′ of FIG. 2A. FIG. 3B is a cross-sectional view of a display device taken along a line IIIb-IIIb′ of FIG. 2B.

Particularly, FIG. 2A is an enlarged view of a pixel disposed in a center portion of the active area AA and FIG. 2B is an enlarged view of a pixel disposed in an edge portion of the active area AA. FIG. 3A illustrates a cross-sectional view of a blue sub pixel SPB disposed in a center portion of the active area AA and cross-sectional views of a red sub pixel SPR and a green sub pixel SPG are also the same as the cross-sectional view of the blue sub pixel SPB. FIG. 3B illustrates a cross-sectional view of a red sub pixel SPR disposed in an edge portion of the active area AA and a cross-sectional view of a green sub pixel SPG is also the same as the cross-sectional view of the red sub pixel SPR. In the meantime, the cross-sectional view of the blue sub pixel SPB disposed in an edge portion of the active area AA is the same as the cross-sectional view of the blue sub pixel SPB disposed in a center portion of the active area AA.

Referring to FIGS. 1 to 3B, a display device 100 according to the example embodiment of the present disclosure includes a substrate 110, a light shielding layer LS, a first buffer layer 111, a first transistor TR1, a second transistor TR2, a gate insulating layer 112, an interlayer insulating layer 113, a second buffer layer 114, a first planarization layer 115, a second planarization layer 116, a third planarization layer 117, a fourth planarization layer 118, a first bank 119a, a second bank 119b, a light emitting diode 120, an encapsulation layer 130, a touch buffer layer 141a, a touch interlayer insulating layer 141b, a first organic layer 142a, a second organic layer 142b, a touch connection electrode 143, a touch electrode 144, a black matrix BM, a color filter CF, and a capping layer 150.

First, referring to FIG. 1, the substrate 110 can be a member which supports other components of the display device 100. The substrate 110 is formed of an insulating material. The substrate 110 includes a first substrate 110a, a second substrate 110b, and an interlayer insulating film 110c. The interlayer insulating film 110c can be disposed between the first substrate 110a and the second substrate 110b. As described above, the substrate 110 is configured by the first substrate 110a, the second substrate 110b, and the interlayer insulating film 110c to suppress the moisture permeation. For example, the first substrate 110a and the second substrate 110b can be polyimide (PI) substrates and the interlayer insulating film 110c can be formed of a single layer of silicon nitride (SiNx) or silicon oxide (SiOx) or multiple layers thereof, but are not limited thereto. For example, in the substrate 110, an active area AA and a non-active area NA are defined. However, the active area AA and the non-active area NA are not defined only in the substrate 110, but can be defined for the overall display device 100.

The active area AA is an area in which images are displayed in the display device 100. In the active area AA, a plurality of sub pixels which configures the plurality of pixels PX and a circuit for driving the plurality of sub pixels can be disposed. The plurality of sub pixels is a minimum unit which configures the active area AA, for example, three sub pixels form one pixel PX. For example, the red sub pixel SPR, the green sub pixel SPG, and the blue sub pixel SPB can form one pixel PX. In the meantime, the red sub pixel SPR, the green sub pixel SPG, and the blue sub pixel SPB can have different sizes. For example, the size of the blue sub pixel SPB can be larger than the sizes of the red sub pixel SPR and the green sub pixel SPG. Therefore, an area of a blue emission layer disposed in the blue sub pixel SPB is larger than areas of a red emission layer disposed in the red sub pixel SPR and a green emission layer disposed in the green sub pixel SPG, but is not limited thereto. The red sub pixel SPR, the green sub pixel SPG, and the blue sub pixel SPB can also be referred to as a first sub pixel, a second sub pixel and a third sub pixel, respectively, but the present disclosure is not limited thereto.

In each of the plurality of sub pixels, a light emitting diode 120 and a thin film transistor for driving the light emitting diode 120 can be disposed. The plurality of light emitting diodes 120 can be defined in different ways depending on the type of the display device. For example, when the display device is an organic light emitting display device, the light emitting diode can be an organic light emitting diode (OLED).

Referring to FIGS. 2A and 2B, in the active area AA, a plurality of emission areas EA and a plurality of non-emission areas NEA can be disposed.

Specifically, each sub pixel disposed in the active area AA includes a plurality of emission areas EA. For example, the plurality of emission areas EA include a first emission area EA1 and a second emission area EA2 which encloses the first emission area EA1. The first emission area EA1 and the second emission area EA2 can be divided by a first non-emission area NEA1 of the plurality of non-emission areas NEA, which will be described below.

In the meantime, in the sub pixels which are disposed in the center portion of the active area AA and the edge portion of the active area AA, the structures of the second emission areas EA2 can be different. For example, referring to FIGS. 1 and 2A, in the sub pixel disposed in the center portion of the active area AA, the width of the second emission area EA2 can be symmetric to each other. For example, parts of the second emission area EA2 which are opposite to each other with respect to a virtual line passing through a center of the sub pixel and parallel to any one of four sides of the sub pixel can have the same width. For example, the width of the second emission area EA2 can be equal regardless of the direction.

In contrast, referring to FIGS. 1 and 2B, in some sub pixels, among sub pixels disposed in the edge portion of the active area AA, for example, in the red sub pixel SPR and the green sub pixel SPG, the width of the second emission area EA2 can be asymmetric. For example, parts of the second emission area EA2 which are opposite to each other with respect to a virtual line passing through a center of each sub pixel and parallel to any one of four sides of the sub pixel can have different widths.

Specifically, a width of a part of the second emission area EA2 which is adjacent to the non-active area NA can be larger than a width of a part of the second emission area EA2 which is adjacent to the center portion of the active area AA. For example, in FIGS. 1 and 2B, a left side of the sub pixel is adjacent to the non-active area NA and a right side of the sub pixel is adjacent to the center portion of the active area AA. At this time, in the red sub pixel SPR and the green sub pixel SPG disposed in a left edge portion of the active area AA, a part of the second emission area EA2 located at the left side has a width larger than that of a part of the second emission area EA2 located at the right side.

This can be implemented by an asymmetric structure of the first electrode 121 of the light emitting diode 120 to be described below. With regard to this, it will be described in detail with reference to FIG. 3B to be described below.

Specifically, each sub pixel disposed in the active area AA includes a plurality of non-emission areas. The plurality of non-emission areas NEA include a first non-emission area NEA1 and a second non-emission area NEA2.

The first non-emission area NEA1 is disposed between the first emission area EA1 and the second emission area EA2. The first non-emission area NEA1 can be a black state or have a luminance lower than that of the first emission area EA1 and the second emission area EA2 due to light which is incident from at least one of the first emission area EA1 and the second emission area EA2, but is not limited thereto.

In the meantime, even though in FIG. 2B, it is illustrated that the width of the first non-emission area NEA1 is symmetric, in some example embodiments of the present disclosure, the width of the first non-emission area NEA1 can be also asymmetric, but is not limited thereto.

The second non-emission area NEA2 encloses the second emission area EA2. The second non-emission area NEA2 is an area corresponding to an area in which a circuit for driving the first emission area EA1 and the second emission area EA2 is disposed. The second non-emission area NEA2 is a black state and the luminance is lower than that of the first emission area EA1 and the second emission area EA2 due to the light incident from the second emission area EA2, but is not limited thereto. The first non-emission area NEA1 is disposed closer to an emission layer disposed in the sub pixel than the second non-emission area NEA2.

In the meantime, in the sub pixels which are disposed in the center portion of the active area AA and the edge portion of the active area AA, some configurations can have different structures. With regard to this, it will be described in detail with reference to FIGS. 3A and 3B to be described below.

In the active area AA, a plurality of signal lines which transmits various signals to the plurality of sub pixels is disposed. For example, the plurality of signal lines includes a plurality of data lines which supplies a data voltage to each of the plurality of sub pixels and a plurality of scan lines which supplies a gate voltage to each of the plurality of sub pixels. The plurality of scan lines extends in one direction in the active area AA to be connected to the plurality of sub pixels and the plurality of data lines extends in a direction different from the one direction in the active area AA to be connected to the plurality of sub pixels. In addition, in the active area AA, a low potential power line and a high potential power line can be further disposed, but are not limited thereto. Referring to FIG. 1 again, the non-active area NA is an area where images are not displayed so that the non-active area NA can be defined as an area extending from the active area AA. In the non-active area NA, a link line which transmits a signal to the sub pixel of the active area AA, a pad electrode, or a driving IC (integrated circuit), such as a gate driver IC or a data driver IC, can be disposed. The non-active area NA can be located on a rear surface of the substrate 110, for example, a surface on which the sub pixels are not disposed or can be omitted, and is not limited as illustrated in the drawing.

Referring to FIGS. 3A and 3B, the first buffer layer 111 is disposed on the substrate 110. The first buffer layer 111 can reduce permeation of moisture or impurities through the substrate 110. The first buffer layer 111 can be configured by a double layer including a substrate buffer layer 111a and an active buffer layer 111b, but is not limited thereto and can be formed by a single layer.

The substrate buffer layer 111a is disposed on the substrate 110. The substrate buffer layer 111a can be configured by a single layer or a double layer of silicon oxide SiOx or silicon nitride SiNx, but is not limited thereto.

The active buffer layer 111b is disposed on the substrate buffer layer 111a. The active buffer layer 111b protects a first light shielding layer LS1 and blocks various types of defects introduced from the substrate 110. For example, the active buffer layer 111b includes at least any one of a-Si, silicon nitride (SiNx), and silicon oxide (SiOx).

However, the first buffer layer 111 can be omitted depending on a type of substrate 110 or a type of transistor, but is not limited thereto.

The first transistor TR1 including a first active layer A1, a first gate electrode G1, a first source electrode S1, and a first drain electrode D1 is disposed on the first buffer layer 111.

The first active layer A1 of the first transistor TR1 is disposed on the first buffer layer 111. The first active layer A1 is disposed on the first buffer layer 111 so as to overlap the first light shielding layer LS1. The first active layer A1 can include amorphous silicon or polycrystalline silicon. For example, the first active layer A1 can include a low-temperature polycrystalline silicon LTPS. For example, the polycrystalline silicon material has a high mobility (100 cm²/Vs or higher) so that energy power consumption is low and reliability is excellent. Therefore, the polysilicon material can be applied to a gate driver for driving elements which drive transistors for a display element and/or a multiplexer (MUX) and also applied as an active layer of a switching transistor of the display device 100 according to the example embodiment, but is not limited thereto. For example, the polycrystalline silicon material can also be applied as an active layer of a switching transistor according to the characteristic of the display device 100. An amorphous silicon (a-Si) material is deposited on the first buffer layer 111 and a dehydrogenation process and a crystallization process are performed to form polycrystalline silicon and the polycrystalline silicon is patterned to form the first active layer A1. Here, the first active layer A1 includes a first channel region in which a channel is formed when the first transistor TR1 is driven and a first source region and a first drain region on both sides of the first channel region. The first source region refers to a part of the first active layer A1 which is connected to the first source electrode S1 and the first drain region refers to a part of the first active layer A1 which is connected to the first drain electrode D1. For example, the first source region and the first drain region are configured by ion-doping (impurity doping) of the first active layer A1. The first source region and the first drain region can be generated by doping ions into the polycrystalline silicon material and the first channel region can refer to a part in which the ions are not doped, but the polycrystalline silicon material remains.

The first gate insulating layer 112a is disposed on the first active layer A1. The first gate insulating layer 112a is an insulating layer which insulates the first active layer A1 from the first gate electrode G1 and can be configured by a single layer or a double layer of silicon oxide (SiOx) or silicon nitride (SiNx), but is not limited thereto. In the first gate insulating layer 112a, a contact hole through which the first source electrode S1 and the first drain electrode D1 of the first transistor TR1 are connected to the first source region and the first drain region of the first active layer A1 of the first transistor TR1, respectively, can be formed.

The first gate electrode G1 of the first transistor TR1 can be disposed on the first gate insulating layer 112a. The first gate electrode G1 can be configured by a conductive material, such as copper (Cu), aluminum (Al), molybdenum (Mo), nickel (Ni), titanium (Ti), chrome (Cr), or an alloy thereof, but is not limited thereto.

A first capacitor electrode C1 of the storage capacitor Cst can be disposed on the first gate insulating layer 112a. The first capacitor electrode C1 can be omitted based on a driving characteristic of the display device 100 and a structure and a type of the transistor. The first gate electrode G1 and the first capacitor electrode C1 can be formed by the same process. Further, the first gate electrode G1 and the first capacitor electrode C1 can be formed of the same material on the same layer, but are not limited thereto. The first interlayer insulating layer 113a can be disposed on the first gate insulating layer 112a, the first gate electrode G1, and the first capacitor electrode C1. In the first interlayer insulating layer 113a, a contact hole for exposing the first source region and the first drain region of the first active layer A1 of the first transistor TR1 can be formed. The first interlayer insulating layer 113a is an insulating layer which protects components below the second buffer layer 114 and can be configured by a single layer or a double layer of silicon oxide (SiOx) or silicon nitride (SiNx), but is not limited thereto.

A second capacitor electrode C2 of the storage capacitor Cst can be disposed on the first interlayer insulating layer 113a. The second capacitor electrode C2 can be formed by a single layer or a multiple layer formed of any one of molybdenum (Mo), copper (Cu), titanium (Ti), aluminum (Al), chrome (Cr), gold (Au), nickel (Ni), and neodymium (Nd) or an alloy thereof. The second capacitor electrode C2 can be formed on the first interlayer insulating layer 113a so as to overlap the first capacitor electrode C1. Further, the second capacitor electrode C2 can be formed of the same material as the first capacitor electrode C1. The second capacitor electrode C2 can be omitted based on a driving characteristic of the display device 100 and a structure and a type of the transistor, but is not limited thereto.

The second buffer layer 114 can be disposed on the first interlayer insulating layer 113a and the second capacitor electrode C2. The second buffer layer 114 can be configured by a single layer of silicon nitride (SiNx) or silicon oxide (SiOx) or a multi-layer thereof. A contact hole for exposing the first source region and the first drain region of the first active layer A1 of the first transistor TR1 can be formed in the second buffer layer 114. Further, in the second buffer layer 114, a contact hole for exposing the second capacitor electrode C2 of the storage capacitor Cst can be formed.

The second active layer A2 of the second transistor TR2 can be disposed on the second buffer layer 114. Here, the second transistor TR2 can include a second active layer A2, a second gate insulating layer 112b, a second gate electrode G2, a second source electrode S2, and a second drain electrode D2. Here, depending on the design of the pixel circuit, the second source electrode S2 can serve as a drain electrode and the second drain electrode D2 can serve as a source electrode.

Further, the second active layer A2 includes a second channel region in which a channel is formed when the second transistor TR2 is driven and a second source region and a second drain region on both sides of the second channel region. The second source region refers to a part of the second active layer A2 which is connected to the second source electrode S2 and the second drain region refers to a part of the second active layer A2 which is connected to the second drain electrode D2.

The second active layer A2 can be formed of an oxide semiconductor. The oxide semiconductor material has a larger band gap than a silicon material so that electrons cannot jump over the band gap in an off state. Therefore, the oxide semiconductor material has a low off-current. The transistor including an active layer which is formed of an oxide semiconductor is suitable for a switching transistor which maintains short on-time and long off-time, but is not limited thereto. Depending on the characteristic of the display device 100, the oxide semiconductor can be applied as a driving transistor. Further, due to the small off-current, a magnitude of an auxiliary capacitance can be reduced so that the oxide semiconductor can be appropriate for a high resolution display element. For example, the second active layer A2 can be formed of metal oxide and for example, can be formed of various metal oxides such as indium-gallium-zinc-oxide (IGZO). Here, the description was made under assumption that the second active layer A2 of the second transistor TR2 is configured by IGZO, among various metal oxides, but it is not limited thereto. Therefore, the second active layer A2 can be formed of another metal oxide such as indium-zinc-oxide (IZO), indium-gallium-tin-oxide (IGTO), or indium-gallium-oxide (IGO), rather than IGZO.

The second active layer A2 can be formed by depositing the metal oxide on the second buffer layer 114, performing a heat treatment for stabilization, and then patterning the metal oxide.

The second gate insulating layer 112b can be disposed on the entire substrate 110 including the second active layer A2. For example, the second gate insulating layer 112b can be configured by a single layer of silicon nitride SiNx or silicon oxide SiOx or a multilayer thereof.

The second gate electrode G2 can be disposed on the second gate insulating layer 112b.

The second gate electrode G2 can be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

For example, a metal material is formed on the second gate insulating layer 112b, a photoresist pattern is formed on the metal material, and then the metal material is wet-etched using the photoresist pattern as a mask to form the second gate electrode G2. As a wet etchant for etching the metal material, a material which selectively etches molybdenum (Mo), copper (Cu), titanium (Ti), aluminum (Al), chrome (Cr), gold (Au), nickel (Ni), and neodymium (Nd) or an alloy thereof which configures the metal material but does not etch the insulating material can be used.

The second interlayer insulating layer 113b is disposed on the second gate insulating layer 112b and the second gate electrode G2. A contact hole for exposing the first active layer A1 of the first transistor TR1 and the second active layer A2 of the second transistor TR2 can be formed in the second interlayer insulating layer 113b. For example, a contact hole for exposing the first source region and the first drain region of the first active layer A1 of the first transistor TR1 can be formed in the second interlayer insulating layer 113b. A contact hole for exposing the second source region and the second drain region of the second active layer A2 of the second transistor TR2 can be formed in the second interlayer insulating layer 113b.

The second interlayer insulating layer 113b can be configured as a single layer of silicon nitride SiNx or silicon oxide SiOx or a multi-layer thereof.

The auxiliary electrode AE, the first source electrode S1 and the first drain electrode D1 of the first transistor TR1 and the second source electrode S2 and the second drain electrode D2 of the second transistor TR2 can be disposed on the second interlayer insulating layer 113b.

The auxiliary electrode AE can be electrically connected to the second drain electrode D2 of the second transistor TR2. Further, the auxiliary electrode AE can be electrically connected to the second capacitor electrode C2 of the storage capacitor Cst through the contact holes formed in the second buffer layer 114 and the second interlayer insulating layer 113b. For example, the auxiliary electrode AE can serve to electrically connect the second capacitor electrode C2 of the storage capacitor Cst and the second drain electrode D2 of the second transistor TR2 to each other.

Here, the first source electrode S1 and the first drain electrode D1 of the first transistor TR1 can be connected to the first active layer A1 of the first transistor TR1 through the contact holes formed in the first gate insulating layer 112a, the first interlayer insulating layer 113a, the second buffer layer 114, the second gate insulating layer 112b and the second interlayer insulating layer 113b.

The second source electrode S2 and the second drain electrode D2 of the second transistor TR2 can be connected to the second active layer A2 of the second transistor TR2 through the contact holes formed in the second gate insulating layer 112b and the second interlayer insulating layer 113b.

The auxiliary electrode AE, the first source electrode S1 and the first drain electrode D1 of the first transistor TR1 and the second source electrode S2 and the second drain electrode D2 of the second transistor TR2 can be formed of the same material by the same process.

For example, the auxiliary electrode AE, the first source electrode S1 and the first drain electrode D1 of the first transistor TR1 and the second source electrode S2 and the second drain electrode D2 of the second transistor TR2 can be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. For example, the auxiliary electrode AE, the first source electrode S1 and the first drain electrode D1 of the first transistor TR1 and the second source electrode S2 and the second drain electrode D2 of the second transistor TR2 can be formed of a triple layered structure of titanium (Ti)/aluminum (Al)/titanium (Ti), but are not limited thereto.

The auxiliary electrode AE can be integrally formed to be connected to the second drain electrode D2 of the second transistor TR2, but is not limited thereto.

In the first transistor TR1, a first light shielding layer LS1 is disposed below the first active layer A1. In the second transistor TR2, a second light shielding layer LS2 is disposed below the second active layer A2. The first light shielding layer LS1 is disposed between the substrate buffer layer 111a and the active buffer layer 111b so as to overlap the first active layer A1 and the second light shielding layer LS2 is disposed between the first gate insulating layer 112a and the first insulating layer 113a so as to overlap the second active layer A2. Therefore, the first light shielding layer LS1 can be insulated from the first active layer A1 and the second light shielding layer LS2 can be insulated from the second active layer A2.

The first light shielding layer LS1 and the second light shielding layer LS2 are formed of a metal material having low light transmittance and reflect light which is incident onto the first active layer A1 and the second active layer A2, below the first active layer A1 and the second active layer A2, respectively. The first light shielding layer LS1 and the second light shielding layer LS2 shield light which is incident onto the first active layer A1 and the second active layer A2 and protects the first active layer A1 and the second active layer A2, respectively.

For example, each of the first light shielding layer LS1 and the second light shielding layer LS2 is referred to as a bottom shield metal (BSM), but is not limited thereto. Specifically, each of the first light shielding layer LS1 and the second light shielding layer LS2 can be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The first planarization layer 115 can be disposed on the auxiliary electrode AE, the first source electrode S1 and the first drain electrode D1 of the first transistor TR1, the second source electrode S2 and the second drain electrode D2 of the second transistor TR2, and the second interlayer insulating layer 113b. The first planarization layer 115 can planarize an upper portion of the pixel circuit including the first transistor TR1 and the second transistor TR2. The first planarization layer 115 can be configured by a single layer or a double layer, and for example, configured by benzocyclobutene or an acrylic organic material, but is not limited thereto. In the meantime, in the first planarization layer 115, a contact hole which allows a connection electrode CE to be connected to the second drain electrode D2 of the second transistor TR2 can be formed.

The connection electrode CE is disposed on the first planarization layer 115. The connection electrode CE electrically connects the second drain electrode D2 of the second transistor TR2 and the first electrode 121 of the light emitting diode 120 through a contact hole formed in the first planarization layer 115. The connection electrode CE can be formed of a single layer or a multiple layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The second planarization layer 116 can be disposed on the first planarization layer 115 and the connection electrode CE. Like the first planarization layer 115, the second planarization layer 116 can planarize an upper portion of the pixel circuit including the first transistor TR1 and the second transistor TR2. The second planarization layer 116 can be configured by a single layer or a double layer, and for example, configured by benzocyclobutene or an acrylic organic material, but is not limited thereto. In the meantime, in the second planarization layer 116, a contact hole which allows the first electrode 121 of the light emitting diode 120 to be connected to the connection electrode CE can be formed, but is not limited thereto.

The third planarization layer 117 can be disposed on the second planarization layer 116. Like the first planarization layer 115 and the second planarization layer 116, the third planarization layer 117 can planarize an upper portion of the pixel circuit including the first transistor TR1 and the second transistor TR2. The third planarization layer 117 can be configured by a single layer or a double layer, and for example, configured by benzocyclobutene or an acrylic organic material, but is not limited thereto. In the meantime, in the third planarization layer 117, a contact hole which allows the first electrode 121 of the light emitting diode 120 to be connected to the connection electrode CE can be formed, but is not limited thereto.

The fourth planarization layer 118 can be disposed on the third planarization layer 117. Like the first planarization layer 115, the second planarization layer 116, and the third planarization layer 117, the fourth planarization layer 118 can planarize an upper portion of the pixel circuit including the first transistor TR1 and the second transistor TR2. The fourth planarization layer 118 can be configured by a single layer or a double layer, and for example, configured by benzocyclobutene or an acrylic organic material, but is not limited thereto. In the meantime, in the fourth planarization layer 118, a contact hole which allows the first electrode 121 of the light emitting diode 120 to be connected to the connection electrode CE can be formed, but is not limited thereto. The first planarization layer 115, the second planarization layer 116, the third planarization layer 117, and the fourth planarization layer 118 can be collectively referred to as a planarization layer.

The fourth planarization layer 118 includes a base portion 118a and a protrusion portion 118b disposed on the base portion 118a. The base portion 118a and the protrusion portion 118b can be integrally formed, as illustrated in FIGS. 3A and 3B. For example, the base portion 118a and the protrusion portion 118b are formed of the same material, by the same process, simultaneously, for example, formed by a half-tone mask process, but are not limited thereto. Therefore, the base portion 118a and the protrusion portion 118b are formed of the same material, but can be configured as separate layers which are formed by different processes.

The base portion 118a is disposed on the pixel circuit including the first transistor TR1 and the second transistor TR2. A top surface of the base portion 118a is configured to be flat. Therefore, the base portion 118a planarizes a step generated due to components disposed therebelow. For example, a step which can be generated by the pixel circuit including the first transistor TR1 and the second transistor TR2 disposed below the fourth planarization layer 118 can be planarized.

The protrusion portion 118b can be disposed on the base portion 118a. The protrusion portion 118b is disposed in an area excluding the first emission area EA1 and is integrally formed with the base portion 118a to have a protruding shape from the base portion 118a. The protrusion portion 118b serves as a spacer which suppresses mask stamping by a deposition process of the emission layer 122, but is not limited thereto.

In the meantime, the protrusion portion 118b can have different structures in the center portion of the active area AA and the edge portion of the active area AA. For example, referring to FIG. 3A, the protrusion portion 118b can have a symmetric structure in the sub pixel disposed in the center portion of the active area AA. For example, widths of the protrusion portions 118b disposed on both sides of the emission layer 122 with respect to the emission layer 122 can be equal to each other.

In contrast, referring to FIG. 3B, in some sub pixel disposed in the edge portion of the active area AA, the protrusion portion 118b can have an asymmetric structure. For example, the protrusion portion 118b can have an asymmetric structure in the red sub pixel SPR and the green sub pixel SPG disposed in the edge portion of the active area AA. For example, in the red sub pixel SPR and the green sub pixel SPG disposed in the edge portion of the active area AA, widths of the protrusion portions 118b disposed on both sides of the emission layer 122 with respect to the emission layer 122 can be different from each other.

For example, a part of the protrusion portion 118b disposed in each sub pixel disposed in the edge portion of the active area AA, which is adjacent to the center portion of the active area AA, is referred to as a first protrusion part 118b-1 and a part of the protrusion portion 118b adjacent to the non-active area NA is referred to as a second protrusion part 118b-2. At this time, in the blue sub pixel SPB disposed in the edge portion of the active area AA, the first protrusion part 118b-1 and the second protrusion part 118b-2 are symmetric to each other. In contrast, in the red sub pixel SPR and the green sub pixel SPG, a width of the second protrusion part 118b-2 is larger than a width of the first protrusion part 118b-1. For example, a left side of FIG. 3B is a portion adjacent to a center portion of the active area AA and a right side is a portion adjacent to the non-active area NA so that a width of the second protrusion part 118b-2 disposed on the right side on the base portion 118a is larger than a width of the first protrusion part 118b-1 disposed on the left side. For example, the second protrusion part 118b-2 of the protrusion portion 118b has a larger horizontal width and a larger vertical height than those of the first protrusion part 118b-1 of the protrusion portion 118b, but is not limited thereto. For another example, the second protrusion part 118b-2 may have a length longer than that of the first protrusion part 118b-1 so as to define an asymmetric structure of the protrusion portion 118b.

The protrusion portion 118b is formed to have an asymmetric structure in the edge portion of the active area AA so that the first electrode 121 disposed on the protrusion portion 118b also has an asymmetric structure. For example, a width of a part of the first electrode 121 disposed on the second protrusion part 118b-2 which is a part of the protrusion portion 118b adjacent to the non-active area NA can be implemented to be larger than a width of a part of the first electrode 121 disposed on the first protrusion part 118b-1 which is a part of the protrusion portion 118b adjacent to the center portion of the active area AA. Therefore, in the area adjacent to the non-active area NA, a reflectable area is increased by the first electrode 121 so that light is more effectively reflected to allow light which is directed to the non-active area NA to be directed to the active area AA.

The light emitting diode 120 can be disposed on the fourth planarization layer 118. The light emitting diode 120 can include a first electrode 121, an emission layer 122, and a second electrode 123 which are sequentially laminated.

The first electrode 121 can be disposed on the fourth planarization layer 118. Specifically, the first electrode 121 can be disposed on the base portion 118a to enclose the side surface of the protrusion portion 118b. The first electrode 121 is a layer for supplying holes to the emission layer 122 and can be an anode. The first electrode 121 is a layer for supplying holes to the emission layer 122 and is formed of a conductive material having a high work function. The first electrode 121 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The first electrode 121 can include a first electrode part 121-1, a second electrode part 121-2, and a third electrode part 121-3.

The first electrode part 121-1 of the first electrode 121 is a part which is in contact with the emission layer 122, for example, a part which is disposed in the first emission area EA1 and functions to allow the light emitting diode 120 to substantially emit light together with the emission layer 122 and the second electrode 123.

The second electrode part 121-2 and the third electrode part 121-3 of the first electrode 121 are disposed to be spaced apart from the emission layer 122.

For example, the second electrode part 121-2 of the first electrode 121 can be a part which is spaced apart from the emission layer 122 and the first bank 119a, for example, can be a part which is exposed by the emission layer 122 and the first bank 119a. Therefore, the second electrode part 121-2 of the first electrode 121 serves as a reflector which reflects light directed to the second electrode part 121-2 of the first electrode 121 from the first emission area EA1 to the front surface.

For example, the second electrode part 121-2 of the first electrode 121 can be disposed in the first non-emission area NEA1 and the second emission area EA2. Specifically, a part of the second electrode part 121-2 of the first electrode 121 which is disposed on the base portion 118a can be disposed in the first non-emission area NEA1. In contrast, a part of the second electrode part 121-2 of the first electrode 121 which is disposed on the side surface of the protrusion portion 118b can be disposed in the second emission area EA2. A part of the second electrode part 121-2 of the first electrode 121 which is disposed on the top surface of the protrusion portion 118b can be disposed in the second non-emission area NEA2, but is not limited thereto.

The third electrode part 121-3 of the first electrode 121 can be disposed in the second non-emission area NEA2. The third electrode part 121-3 of the first electrode 121 is disposed to be spaced apart from the emission layer 122, like the second electrode part 121-2 of the first electrode 121, and is covered by the first bank 119a. Therefore, from the first emission area EA1, light directed to the third electrode part 121-3 of the first electrode 121 is absorbed by the first bank 119a so that the light is not emitted to the adjacent sub pixel.

For example, each of the red sub pixel SPR and the green sub pixel SPG has the same size in each of the center portion of the active area AA and the edge portion of the active area AA and a width of the second electrode part 121-2 of the first electrode 121 disposed in the edge portion of the active area AA is adjusted to improve the reflection efficiency.

First, referring to FIGS. 1, 2A, and 3A, in each of the sub pixels disposed in the center portion of the active area AA, the second electrode part 121-2 of the first electrode 121 can be symmetric. For example, in all the red sub pixel SPR, the green sub pixel SPG, and the blue sub pixel SPB disposed in the center portion of the active area AA, the second electrode part 121-2 of the first electrode 121 can be symmetric. Therefore, light emitted from the first emission area EA1 is uniformly reflected by the second electrode part 121-2 of the first electrode 121 to maintain a uniform display quality.

In the meantime, referring to FIGS. 1, 2B, and 3B, in the red sub pixel SPR and the green sub pixel SPG disposed in the edge portion of the active area AA, the second electrode part 121-2 of the first electrode 121 can have an asymmetric structure. For example, a width of the second protrusion part 118b-2 of the protrusion portion 118b which is adjacent to the non-active area NA is larger than a width of the first protrusion part 118b-1 of the protrusion portion 118b which is adjacent to the center portion of the active area AA. A width of a part of the second electrode part 121-2 of the first electrode 121 disposed on the second protrusion part 118b-2 of the protrusion portion 118b is implemented to be larger than a width of a part of the second electrode part 121-2 of the first electrode 121 disposed on the first protrusion part 118b-1 of the protrusion portion 118b. The width of the part of the second electrode part 121-2 of the first electrode 121 which is adjacent to the non-active area NA is larger than the width of the part of the second electrode part 121-2 of the first electrode 121 which is adjacent to the center portion of the active area AA. For example, in the red sub pixel SPR and the green sub pixel SPG disposed in the edge portion of the active area AA, in an area adjacent to the non-active area NA, the width of the part of the second electrode part 121-2 of the first electrode 121 can be implemented to be relatively large. Specifically, a width of the side surface of the second protrusion part 118b-2 of the protrusion portion 118b is larger than a width of the side surface of the first protrusion part 118b-1. The width of a part of the second electrode part 121-2 of the first electrode 121 disposed on the side surface of the second protrusion part 118b-2 of the protrusion portion 118b is larger than the width of a part of the second electrode part 121-2 of the first electrode 121 disposed on the side surface of the first protrusion part 118b-1 of the protrusion portion 118b. Therefore, light which is emitted from the emission layer 122 to be directed to the non-active area NA can be more effectively reflected to the active area AA.

At this time, the second electrode part 121-2 of the first electrode 121 which is at least partially disposed in the second emission area EA2 has an asymmetric structure so that the area of the second emission area EA2 is also asymmetric. Specifically, in each of the red sub pixel SPR and the green sub pixel SPG in the edge portion of the active area AA, a width of the side surface of the first protrusion part 118b-1 of the protrusion portion 118b is smaller than a width of the side surface of the second protrusion part 118b-2. Therefore, the width of the part of the electrode second part 121-2 of the first electrode 121 disposed on the side surface of the second protrusion part 118b-2 of the protrusion portion 118b is larger than the width of the part of the second electrode part 121-2 of the first electrode 121 disposed on the side surface of the first protrusion part 118b-1 of the protrusion portion 118b. For example, the part of the second electrode part 121-2 of the first electrode 121 which is disposed on the side surface of the protrusion portion 118b is disposed in the second emission area EA2. An area of the part of the second emission area EA2 adjacent to the non-active area NA is larger than the part of the second emission area EA2 adjacent to the center portion of the active area AA, but is not limited thereto. The first bank 119a is disposed on the fourth planarization layer 118 and the first electrode 121. The first bank 119a is disposed so as to cover at least a part of the first electrode 121. The first bank 119a is formed of an insulating material to insulate the first electrodes 121 of the adjacent sub pixels from each other. Further, the first bank 119a is configured as a black bank including a black material having a high light absorption rate to suppress color mixture between the adjacent sub pixels.

In the meantime, the first bank 119a exposes the second electrode part 121-2 of the first electrode 121 disposed on the side surface of the protrusion portion 118b. Therefore, light which is directed to the side surface of the protrusion portion 118b is not absorbed by the first bank 119a, but is reflected by the second electrode part 121-2 of the first electrode 121 to be extracted to the front.

The second bank 119b can be disposed on the first bank 119a and the first electrode 121. The second bank 119b is disposed so as to cover the first bank 119a, and also covers an edge portion of the first electrode 121 to define the first emission area EA1. Specifically, the second bank 119a can be disposed so as to cover the second electrode part 121-2 and the third electrode part 121-3 of the first electrode 121 to be described below. For example, the second bank 119b can be a pixel definition film which divides the plurality of sub pixels, but is not limited thereto.

Like the first bank 119a, the second bank 119b is formed of an insulating material to insulate the first electrodes 121 of the adjacent sub pixels from each other. Unlike the first bank 119a, the second bank 119b is formed of a transparent material. For example, the second bank 119b can be formed of acryl resin, epoxy resin, phenolic resin, polyamide resin, or polyimide resin, but is not limited thereto.

The emission layer 122 is disposed on the first electrode 121. The emission layer 122 is a layer in which electrons and holes are coupled to emit light.

In order to improve luminous efficiency of the light emitting diode 120, a hole injection layer, a hole transport layer, an electron transport layer, and an electron injection layer can be further included. For example, the hole injection layer and the hole transport layer can be disposed between the first electrode 121 and the emission layer 122 and the electron transport layer and the electron injection layer can be disposed between the emission layer 122 and the second electrode 123. Further, a hole blocking layer or an electron blocking layer can also be disposed to further improve a recombination efficiency of the holes and electrons in the emission layer 122.

The second electrode 123 can be disposed on the emission layer 122. The second electrode 123 is a layer which supplies electrons to the emission layer 122 and can be a cathode. The second electrode 123 is formed of a transmissive or semi-transmissive conductive material, for example. For example, the second electrode 123 can be formed of a transparent conductive material such as indium tin oxide (ITO) and indium zinc oxide (IZO), but is not limited thereto.

The encapsulation layer 130 can be disposed on the light emitting diode 120. The encapsulation layer 130 can protect the light emitting diode 120 from moisture, oxygen, and impacts of the outside. The encapsulation layer 130 can be formed with a multilayered structure in which an inorganic layer formed of an inorganic insulating material and an organic layer formed of an organic material are laminated. For example, the encapsulation layer 130 can be configured by at least one organic layer and at least two inorganic layers and have a multilayered structure in which the inorganic layers and the organic layer are alternately laminated, but is not limited thereto. For example, the encapsulation layer 130 can have a triple layered structure including a first inorganic encapsulation layer 131, an organic encapsulation layer 132, and a second inorganic encapsulation layer 133. In this case, the first inorganic encapsulation layer 131 and the second inorganic encapsulation layer 133 can be independently formed of one or more selected from silicon nitride (SiNx), silicon oxide (SiOx), aluminum oxide (AlOx), and silicon oxynitride (SiON), but are not limited thereto. In the meantime, the organic encapsulation layer 132 can be formed of one or more selected from an epoxy resin, polyimide resin, polyethylene resin, and silicon oxycarbide (SiOC), but is not limited thereto.

The touch sensing unit can be disposed on the encapsulation layer 130. Specifically, the touch sensing unit includes a touch buffer layer 141a disposed on the second inorganic encapsulation layer 133, a plurality of touch connection electrodes 143 disposed on the touch buffer layer 141a, a touch interlayer insulating layer 141b disposed on the plurality of touch connection electrodes 143, a plurality of touch electrodes 144 disposed on the touch interlayer insulating layer 141b, a first organic layer 142a disposed so as to cover the plurality of touch electrodes 144, and a second organic layer 142b disposed on the first organic layer 142a.

The touch buffer layer 141a blocks a chemical solution, such as a developer or an etchant, used for the manufacturing process of the touch connection electrode 143 and the touch electrodes 144 disposed on the touch buffer layer 141a or external moisture or foreign materials from permeating into the light emitting diode 120.

The touch buffer layer 141a can be formed of an organic insulating material which is formed at a temperature lower than a predetermined temperature (for example, 100° C.) to suppress the damage of the emission layer 122 including an organic material which is vulnerable to a high temperature. The organic insulating material has a low permittivity of 1 to 3. For example, the touch buffer layer 141a can be formed of acrylic, epoxy, or siloxane based material, but is not limited thereto.

The plurality of touch connection electrodes 143 can be disposed on the touch buffer layer 141a. The plurality of touch connection electrodes 143 electrically connects the plurality of touch electrodes 144 on the touch interlayer insulating layer 141b. For example, the plurality of touch connection electrodes 143 can be formed of a single layer or a multiple layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. For example, the plurality of touch connection electrodes 143 can be formed with a triple structure of titanium (Ti)/aluminum (Al)/titanium (Ti).

The touch interlayer insulating layer 141b is disposed on the touch buffer layer 141a so as to cover the plurality of touch connection electrodes 143 to insulate the plurality of touch connection electrodes 143 and the plurality of touch electrodes 144 from each other. For example, the touch interlayer insulating layer 141b can be configured as a single layer of silicon nitride (SiNx) or silicon oxide (SiOx) or a multi-layer thereof, but is not limited thereto.

The plurality of touch electrodes 144 is disposed on the touch interlayer insulating layer 141b. The plurality of touch electrodes 144 is connected in a column direction to form a plurality of electrode columns and is connected in a row direction by the plurality of touch connection electrodes 143 to form a plurality of electrode rows, but is not limited thereto.

For example, the plurality of touch electrodes 144 can be formed of a single layer or a multiple layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto. For example, the plurality of touch electrodes 144 can also be formed with a triple structure of titanium (Ti)/aluminum (Al)/titanium (Ti), respectively.

The first organic layer 142a is disposed so as to cover the plurality of touch electrodes 144. For example, the first organic layer 142a can be formed of an organic material such as acryl resin, epoxy resin, phenolic resin, polyamide resin, and polyimide resin. The first organic layer 142a suppresses the step of the component disposed therebelow to improve the visibility of the display device 100. For example, the first organic layer 142a is referred to as a first touch planarization layer, but is not limited thereto.

The second organic layer 142b can be disposed on the first organic layer 142a. The second organic layer 142b suppresses a crack of the display device 100 generated due to the external force. Further, the step on the top layer of the display device 100 is suppressed by the second organic layer 142b to further improve the visibility of the display device 100. For example, the second organic layer 142b can be formed of the same material as the first organic layer 142a, but is not limited thereto. For example, the second organic layer 142a is referred to as a second touch planarization layer, but is not limited thereto.

A plurality of black matrices BM is disposed on the second organic layer 142b. The black matrix BM is disposed in the second non-emission area NEA2 in each sub pixel. The black matrix BM can be disposed in an area corresponding to the first bank 119a. The black matrix BM is a black insulating layer to block light from the inside or the outside of the display device 100. Therefore, the black matrix BM suppresses the color mixture of light which passes through the color filter CF.

The color filter CF is disposed on the second organic layer 142b. The color filter CF is disposed so as to correspond to the first emission area EA1, the first non-emission area NEA1, and the second emission area EA2. The color filter CF converts light emitted from the light emitting diode 120 into specific color light. Therefore, the red color filter is disposed in the red sub pixel SPR, the green color filter is disposed in the green sub pixel SPG, and the blue color filter is disposed in the blue sub pixel SPB to convert the light into red light, green light, and blue light, respectively.

The protection layer 150 is disposed on the black matrix BM and the color filter CF. The protection layer 150 planarizes an upper portion of the substrate 110 in which the light emitting diode 120 is disposed and also protects the light emitting diode 120. The protection layer 150 can be configured by a single layer or a double layer, and for example, can be formed of photoresist or an acrylic organic material, but is not limited thereto.

Light emitted from the emission layer 122 of the display device passes through various components of the display device to be released to the outside of the display device. However, some of light emitted from the emission layer 122 is trapped in the display device without being released to the outside of the display device so that the light extraction efficiency of the display device becomes an issue.

For example, there is a problem in that some of light emitted from the emission layer 122 is trapped in the display device due to a total reflection loss, a waveguide loss, and a surface plasmon loss. Here, the total reflection loss refers to degradation of the light extraction efficiency due to light trapped in the display device due to the total reflection at an interface between a substrate and air, among the light emitted from the emission layer 122. The waveguide loss refers to degradation of the light extraction efficiency caused by light trapped therein due to the total reflection at the interface of components in the display device. At this time, the interface of internal components which cause the total reflection can refer to an interface parallel to the substrate. Next, the surface plasmon loss refers to that the light vibrates free electrons of the metal surface due to a phenomenon that light is absorbed onto a metal surface during a process of entering and propagating the light so that the light cannot be reflected or transmitted to degrade the light extraction efficiency.

The light loss causes increase of power consumption of the display device and the reduction in the lifespan of the light emitting diode so that various efforts are continued to improve the light extraction efficiency.

In the display device 100 according to the example embodiment of the present disclosure, the light extraction efficiency of the light emitting diode 120 can be improved using the fourth planarization layer 118 including the protrusion portion 118b. For example, in the display device 100 according to the example embodiment of the present disclosure, the fourth planarization layer 118 includes the base portion 118a and the protrusion portion 118b protruding from the base portion 118a and the first electrode 121 of the light emitting diode 120 is disposed so as to enclose the side surface of the protrusion portion 118b. Light directed to the side surface, among light emitted from the emission layer 122, is reflected by the first electrode 121 disposed on the protrusion portion 118b to be incident at a critical angle or smaller so that the light is extracted toward the front without being trapped in the display device 100 by the total reflection. Therefore, the light extraction efficiency is improved.

Further, in the display device 100 according to the example embodiment of the present disclosure, the first bank 119a includes a black material. Therefore, the color mixture between adjacent sub pixels is suppressed to improve the reflective visibility. Further, the second electrode part 121-2 of the first electrode 121 disposed on the side surface of the protrusion portion 118b is exposed so that light directed to the side surface is not absorbed by the first bank 119a, but is extracted by the second electrode part 121-2 of the first electrode 121.

Generally, a blue emission layer has a shorter lifespan and worse efficiency than a red emission layer or a green emission layer. In order to stably implement the blue, an area of the blue sub pixel is formed to be larger than areas of the red sub pixel and the green sub pixel to relatively increase the area of the blue emission layer. Therefore, in a limited area, the area of the blue sub pixel needs to be ensured so that there is a limitation in increasing the areas of the red sub pixel and the green sub pixel. For example, in the red sub pixel and the green sub pixel, there is a limitation in increasing the area of the emission area so that it is more important to improve the light extraction efficiency so as not to cause the light loss as much as possible.

Therefore, in the display device 100 according to the example embodiment of the present disclosure, the width of the second electrode part 121-2 of the first electrode 121 in the red sub pixel SPR and the green sub pixel SPG is adjusted while maintaining the largest size of the blue sub pixel SPB. By doing this, the reflection efficiency of the red sub pixel SPR and the green sub pixel SPG can be improved. For example, the first electrode 121 disposed in the red sub pixel SPR and the green sub pixel SPG disposed in the edge portion of the active area AA which is adjacent to the non-active area NA can have an asymmetric structure. Specifically, a width of the second electrode part 121-2 of the first electrode 121 exposed by the first bank 119a and the emission layer 122 can be asymmetrically formed. For example, the width of the part of the second electrode part 121-2 of the first electrode 121 which is adjacent to the non-active area NA is formed to be larger than the width of the part of the second electrode part 121-2 of the first electrode 121 which is adjacent to the center portion of the active area AA. For example, the first electrode 121 is disposed so as to enclose the protrusion portion 118b of the fourth planarization layer 118 so that the size of the protrusion portion 118b is asymmetrically formed to implement the width of the second electrode part 121-2 of the first electrode 121 disposed on the side surface of the protrusion portion 142 asymmetrically. For example, the width of the second protrusion part 118b-2 of the protrusion portion 118b which is adjacent to the non-active area NA is formed to be larger than the width of the first protrusion part 118b-1 of the protrusion portion 118b which is adjacent to the center portion of the active area AA by the half-tone process. Therefore, a width of the part of the second electrode part 121-2 of the first electrode 121 which is disposed on the second protrusion part 118b-2 of the protrusion portion 118b can be implemented to be larger than a width of the part of the second electrode part 121-2 of the first electrode 121 which is disposed on the first protrusion part 118b-1 of the protrusion portion 118b. Accordingly, the width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA. For example, in the red sub pixel SPR and the green sub pixel SPG disposed in the edge portion of the active area AA, in an area adjacent to the non-active area NA, a reflectable area is increased by the second electrode part 121-2 of the first electrode 121 so that light which is directed to the non-active area NA is more effectively reflected to the active area AA. For example, in the display device 100 according to the example embodiment of the present disclosure, also in the red sub pixel SPR and the green sub pixel SPG having a relatively small size, the light extraction efficiency is improved to improve the front luminance.

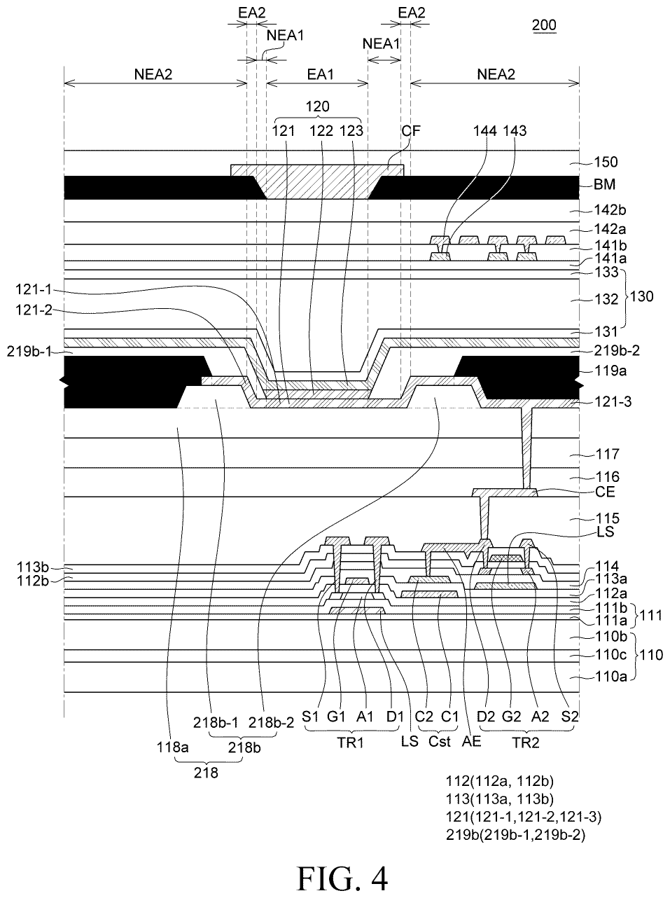

FIG. 4 is a cross-sectional view of the same area as FIG. 3B of a display device according to another example embodiment of the present disclosure. For example, FIG. 4 is a cross-sectional view of a red sub pixel SPR and a green sub pixel SPG disposed in the edge portion of the active area AA. The only difference or one difference between a display device 200 of FIG. 4 and the display device 100 of FIGS. 1 to 3B is a fourth planarization layer 218 and a second bank 219b, but the other configurations are substantially the same, so that a redundant description will be omitted or may be briefly provided.

Referring to FIG. 4, the protrusion portion 218b can have a symmetric structure not only in the red sub pixel SPR, the blue sub pixel SPB, and the green sub pixel SPG in the center portion of the active area AA and the blue sub pixel SPB in the edge portion of the active area AA, but also in the red sub pixel SPR and the green sub pixel SPG in the edge portion of the active area AA. For example, in the edge portion of the active area AA, a width of the second protrusion part 218b-2 of the protrusion portion 218b which is adjacent to the non-active area NA can be equal to the width of the first protrusion part 218b-1 of the protrusion portion 218b which is adjacent to the center portion of the active area AA. For example, the protrusion portion 218 has the same structure in the center portion of the active area AA and the edge portion of the active area AA so that the width of the protrusion portion 218 can be the same regardless of the direction.

Therefore, the width of the second emission area EA2 is also symmetric. For example, the second emission area EA2 is an area corresponding to a part of the side surface of the protrusion portion 218b which is adjacent to the emission layer 121 so that the first protrusion part 218b-1 of the protrusion portion 218b and the second protrusion part 218b-2 of the protrusion portion 218b are symmetric. Further, widths of the second emission area EA2 corresponding to the side surface of the first protrusion part 218b-1 of the protrusion portion 218b and the side surface of the second protrusion part 218b-2 of the protrusion portion 218b are also symmetric, but are not limited thereto.

In the meantime, the second bank 219b can have an asymmetric structure in the red sub pixel SPR and the green sub pixel SPG disposed in the edge portion of the active area AA. For example, a part of the second bank 219b disposed in each sub pixel disposed in the edge portion of the active area AA, which is adjacent to the center portion of the active area AA, is referred to as a first bank part 219b-1 and a part of the second bank 219b adjacent to the non-active area NA is referred to as a second bank part 219b-2. At this time, in the red sub pixel SPR and the green sub pixel SPG disposed in the edge portion of the active area AA, the width of the second bank part 219b-2 of the second bank 219b is larger than the width of the first bank part 219b-1 of the second bank 219b. For example, a left side of FIG. 4 is a portion adjacent to a center portion of the active area AA and a right side is a portion adjacent to the non-active area NA so that a width of the second bank part 219b-2 of the second bank 219b disposed on the right side is larger than a width of the first bank part 219b-1 of the second bank 219b disposed on the left side.

The second bank 219b can have an asymmetric structure in the red sub pixel SPR and the green sub pixel SPG disposed in the edge portion of the active area AA so that the first electrode 121 also has an asymmetric structure. For example, the second bank part 219b-2 of the second bank 219b has a width larger than the first bank part 219b-1 of the second bank 219b so that an area of the base portion 118a covered by the second bank part 219b-2 of the second bank 219b but not by the protrusion portion 218b and the first bank 119a can also be larger than an area of the base portion 118a covered by the first bank part 219b-1 of the second bank 219b but not by the protrusion portion 218b and the first bank 119a. The shortest distance between the emission layer 122 disposed on the base portion 118a and the second protrusion part 218b-2 of the protrusion portion 218b is longer than the shortest distance between the emission layer 122 and the first protrusion part 218b-1 of the protrusion portion 218b. Therefore, the part of the second electrode part 121-2 of the first electrode 121 which is adjacent to the non-active area NA is disposed on the base portion 118a and the protrusion portion 218b wider than the part of the second electrode part 121-2 of the first electrode 121 which is adjacent to the center portion of the active area AA.

The width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA.

Therefore, in the area adjacent to the non-active area NA, a reflectable area is increased by the first electrode 121 so that light is more effectively reflected to allow light which is directed to the non-active area NA to be directed to the active area AA.

In the meantime, the second bank part 219b-2 of the second bank 219b extends onto the base portion 118a more than the first bank part 219b-1 of the second bank 219b so that the second bank part 219b-2 of the second bank 219b has the same height as the first bank part 219b-1 of the second bank 219b, but has a larger horizontal width. The second bank part 219b-2 of the second bank 219b has a slope gentler than the first bank part 219b-1 of the second bank 219b, but is not limited thereto. In the meantime, the width of the first non-emission area NEA1 is also asymmetric. The first non-emission area NEA1 can be an area corresponding to a part of the second bank 219b which covers a part of the second electrode part 121-2 of the first electrode 121 disposed on the base portion 118a but not on the protrusion portion 218b. The second bank part 219b-1 of the second bank 219b extends on the base portion 118a more than the first bank part 219b-1 of the second bank 219b. Therefore, a width of the first non-emission area NEA1 defined by the second bank part 219b-2 of the second bank 219b is larger than a width of the first non-emission area NEA1 defined by the first bank part 219b-1 of the second bank 219b, but is not limited thereto.

In the display device 200 according to another example embodiment of the present disclosure, the light extraction efficiency of the light emitting diode 120 can be improved using the fourth planarization layer 218 including the protrusion portion 218b. For example, in the display device 200 according to another example embodiment of the present disclosure, the fourth planarization layer 218 includes the base portion 118a and the protrusion portion 218b protruding from the base portion 118a and the first electrode 121 of the light emitting diode 120 is disposed so as to enclose the side surface of the protrusion portion 218b. Light directed to the side surface, among light emitted from the emission layer 122, is reflected by the first electrode 121 disposed on the protrusion portion 218b to be incident at a critical angle or smaller so that the light is extracted toward the front without being trapped in the display device 200 by the total reflection. Therefore, the light extraction efficiency is improved.

Further, in the display device 200 according to another example embodiment of the present disclosure, the first bank 119a includes a black material. The color mixture between adjacent sub pixels is suppressed to improve the reflective visibility. Further, the second electrode part 121-2 of the first electrode 121 disposed on the side surface of the protrusion portion 218b is exposed so that light directed to the side surface is not absorbed by the first bank 119a, but is extracted by the second electrode part 121-2 of the first electrode 121.

Therefore, in the display device 200 according to another example embodiment of the present disclosure, the width of the second electrode part 121-2 of the first electrode 121 in the red sub pixel SPR and the green sub pixel SPG is adjusted while maintaining the largest size of the blue sub pixel SPB. By doing this, the reflection efficiency of the red sub pixel SPR and the green sub pixel SPG can be improved. For example, the first electrodes 121 disposed in the red sub pixel SPR and the green sub pixel SPG disposed in the edge portion of the active area AA which is adjacent to the non-active area NA can have an asymmetric structure. Specifically, a width of the second electrode part 121-2 of the first electrode 121 exposed by the first bank 119a and the emission layer 122 can be asymmetrically formed. For example, the width of the part of the second electrode part 121-2 of the first electrode 121 which is adjacent to the non-active area NA is formed to be larger than the width of the part of the second electrode part 121-2 of the first electrode 121 which is adjacent to the center portion of the active area AA. For example, the size of the second bank 219b is asymmetrically formed to implement the width of the second electrode part 121-2 of the first electrode 121 asymmetrically. For example, the width of the second bank part 219b-2 of the second bank 219b which is adjacent to the non-active area NA can be formed to be larger than the width of the first bank part 219b-1 of the second bank 219b which is adjacent to the center portion of the active area AA. As such, the area of the base portion 118a which is covered by the second bank part 219b-2 of the second bank 219b but not by the protrusion portion 218b and the first bank 119a is also larger than the area of the base portion 118a covered by the first bank part 219b-1 of the second bank 219b but not by the protrusion portion 218b and the first bank 119a. The shortest distance between the emission layer 122 disposed on the base portion 118a and the second protrusion part 218b-2 of the protrusion portion 218b is longer than the shortest distance between the emission layer 122 and the first protrusion part 218b-1 of the protrusion portion 218b. The part of the second electrode part 121-2 of the first electrode 121 which is adjacent to the non-active area NA is disposed on the base portion 118a and the protrusion portion 218b wider than the part of the second electrode part 121-2 of the first electrode 121 which is adjacent to the center portion of the active area AA. The width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA. In the part adjacent to the non-active area NA, the reflectable area is increased by the first electrode 121 so that light directed to the non-active area NA can be more effectively reflected to be directed to the active area AA. Therefore, in the red sub pixel SPR and the green sub pixel SPG disposed in the edge portion of the active area AA, in a part adjacent to the non-active area NA, the reflectable area is increased by the second electrode part 121-2 of the first electrode 121 so that light directed to the non-active area NA can be more effectively reflected to the active area AA. For example, in the display device 200 according to another example embodiment of the present disclosure, also in the red sub pixel SPR and the green sub pixel SPG having a relatively small size, the light extraction efficiency is improved to improve the front luminance.

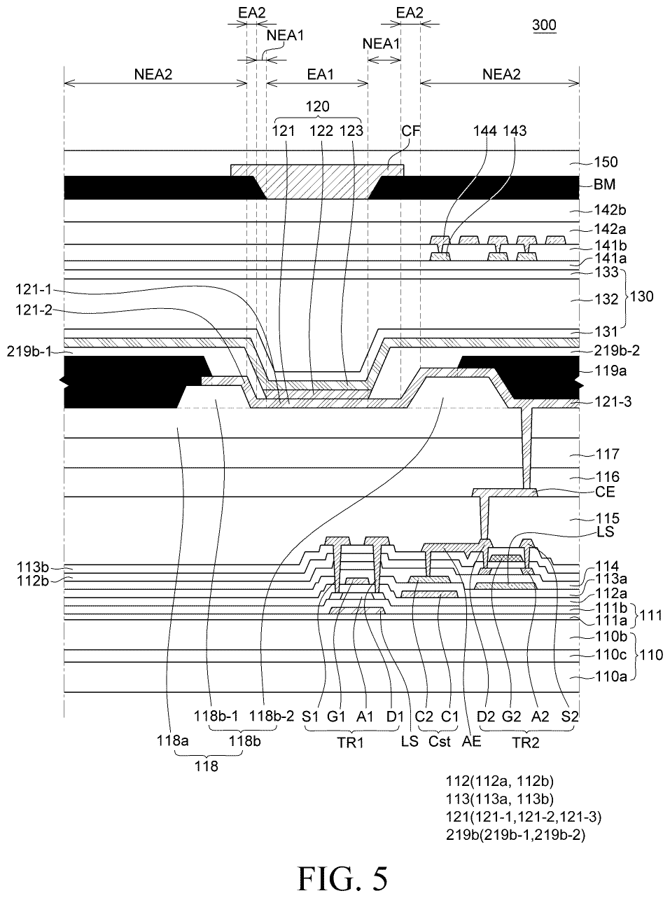

FIG. 5 is a cross-sectional view of the same area as FIG. 3B of a display device according to still another example embodiment of the present disclosure. For example, FIG. 5 is a cross-sectional view of a red sub pixel SPR and a green sub pixel SPG disposed in the edge portion of the active area AA. The only difference or a difference between a display device 300 of FIG. 5 and the display device 100 of FIGS. 1 to 3B is a second bank 219b, but the other configurations are substantially the same, so that a redundant description will be omitted or may be briefly provided.

Referring to FIG. 5, the protrusion portion 118b is formed to have an asymmetric structure in the edge portion of the active area AA so that the first electrode 121 disposed on the protrusion portion 118b also has an asymmetric structure. For example, a width of a part of the first electrode 121 disposed on the second protrusion part 118b-2 which is a part of the protrusion portion 118b adjacent to the non-active area NA is implemented to be larger than a width of a part of the first electrode 121 disposed on the first protrusion part 118b-1 which is a part of the protrusion portion 118b adjacent to the center portion of the active area AA. Therefore, in the area adjacent to the non-active area NA, a reflectable area is increased by the first electrode 121 so that light is more effectively reflected to allow light which is directed to the non-active area NA to be directed to the active area AA.

The second bank 219b can have an asymmetric structure in the red sub pixel SPR and the green sub pixel SPG disposed in the edge portion of the active area AA so that the first electrode 121 also has an asymmetric structure. For example, the second bank part 219b-2 of the second bank 219b has a width larger than the first bank part 219b-1 of the second bank 219b so that an area of the base portion 118a covered by the second bank part 219b-2 of the second bank 219b but not by the protrusion portion 118b and the first bank 119a can be larger than an area of the base portion 118a covered by the first bank part 219b-1 of the second bank 219b but not by the protrusion portion 118b and the first bank 119a. The shortest distance between the emission layer 122 disposed on the base portion 118a and the second protrusion part 118b-2 of the protrusion portion 118b is longer than the shortest distance between the emission layer 122 and the first protrusion part 118b-1 of the protrusion portion 118b. Therefore, the part of the second electrode part 121-2 of the first electrode 121 which is adjacent to the non-active area NA is disposed on the base portion 118a and the protrusion portion 118b relatively wider than the part of the second electrode part 121-2 of the first electrode 121 which is adjacent to the center portion of the active area AA.

The width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA.

In the area adjacent to the non-active area NA, a reflectable area is increased by the first electrode 121 so that light is more effectively reflected to allow light which is directed to the non-active area NA to be directed to the active area AA.

In the meantime, the second bank part 219b-2 of the second bank 219b extends onto the base portion 118a more than the first bank part 219b-1 of the second bank 219b so that the second bank part 219b-2 of the second bank 219b has the same height as the first bank part 219b-1 of the second bank 219b, but has a larger horizontal width. Therefore, the second bank part 219b-2 of the second bank 219b has a slope gentler than the first bank part 219b-1 of the second bank 219b, but is not limited thereto.

In the display device 300 according to still another example embodiment of the present disclosure, the light extraction efficiency of the light emitting diode 120 can be improved using the fourth planarization layer 118 including the protrusion portion 118b. For example, in the display device 300 according to still another example embodiment of the present disclosure, the fourth planarization layer 118 includes the base portion 118a and the protrusion portion 118b protruding from the base portion 118a and the first electrode 121 of the light emitting diode 120 is disposed so as to enclose the side surface of the protrusion portion 118b. Further, light directed to the side surface, among light emitted from the emission layer 122, is reflected by the first electrode 121 disposed on the protrusion portion 118b to be incident at a critical angle or smaller so that the light is extracted toward the front without being trapped in the display device 300 by the total reflection. Therefore, the light extraction efficiency is improved.

Further, in the display device 300 according to still another example embodiment of the present disclosure, the first bank 119a includes a black material. Therefore, the color mixture between adjacent sub pixels is suppressed to improve the reflective visibility. The second electrode part 121-2 of the first electrode 121 disposed on the side surface of the protrusion portion 118b is exposed so that light directed to the side surface is not absorbed by the first bank 119a, but is extracted by the second electrode part 121-2 of the first electrode 121.

Therefore, in the display device 300 according to still another example embodiment of the present disclosure, the width of the second electrode part 121-2 of the first electrode 121 in the red sub pixel SPR and the green sub pixel SPG is adjusted while maintaining the largest size of the blue sub pixel SPB. By doing this, the reflection efficiency of the red sub pixel SPR and the green sub pixel SPG can be improved. For example, the first electrode 121 disposed in the red sub pixel SPR and the green sub pixel SPG disposed in the edge portion of the active area AA which is adjacent to the non-active area NA can have an asymmetric structure. Specifically, a width of the second electrode part 121-2 of the first electrode 121 exposed by the first bank 119a and the emission layer 122 can be asymmetrically formed. For example, the width of the part of the second electrode part 121-2 of the first electrode 121 which is adjacent to the non-active area NA is formed to be larger than the width of the part of the second electrode part 121-2 of the first electrode 121 which is adjacent to the center portion of the active area AA. For example, the first electrode 121 is disposed so as to enclose the protrusion portion 118b of the fourth planarization layer 118 so that the size of the protrusion portion 118b is asymmetrically formed to implement the width of the second electrode part 121-2 of the first electrode 121 disposed on the side surface of the protrusion portion 118b asymmetrically. For example, the width of the second protrusion part 118b-2 of the protrusion portion 118b which is adjacent to the non-active area NA is formed to be larger than the width of the first protrusion part 118b-1 of the protrusion portion 118b which is adjacent to the center portion of the active area AA by the half-tone process. Therefore, a width of a part of the second electrode part 121-2 of the first electrode 121 which is disposed on the second protrusion part 118b-2 of the protrusion portion 118b can be implemented to be larger than a width of a part of the second electrode part 121-2 of the first electrode 121 which is disposed on the first protrusion part 118b-1 of the protrusion portion 118b.

Further, in the display device 300 according to still another example embodiment of the present disclosure, the size of the second bank 219b is also asymmetrically formed to implement the width of the second electrode part 121-2 of the first electrode 121 asymmetrically. For example, the width of the second bank part 219b-2 of the second bank 219b which is adjacent to the non-active area NA can be formed to be larger than the width of the first bank part 219b-1 of the second bank 219b which is adjacent to the center portion of the active area AA. An area of the base portion 118a covered by the second bank part 219b-2 of the second bank 219b but not by the protrusion portion 118b and the first bank 119a can also be larger than an area of the base portion 118a covered by the first bank part 219b-1 of the second bank 219b but not by the protrusion portion 118b and the first bank 119a. The shortest distance between the emission layer 122 disposed on the base portion 118a and the second protrusion part 118b-2 of the protrusion portion 118b is longer than the shortest distance between the emission layer 122 and the first protrusion part 118b-1 of the protrusion portion 118b. The part of the second electrode part 121-2 of the first electrode 121 which is adjacent to the non-active area NA is disposed on top surfaces of the base portion 118a and the protrusion portion 118b relatively wider than the part of the second electrode part 121-2 of the first electrode 121 which is adjacent to the center portion of the active area AA. The width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA. In the area adjacent to the non-active area NA, a reflectable area is increased by the first electrode 121 so that light is more effectively reflected to allow light which is directed to the non-active area NA to be directed to the active area AA. Therefore, in the red sub pixel SPR and the green sub pixel SPG disposed in the edge portion of the active area AA, in a part adjacent to the non-active area NA, a reflectable area is increased by the second electrode part 121-2 of the first electrode 121 so that light directed to the non-active area NA is more effectively reflected to the active area AA. For example, in the display device 300 according to still another example embodiment of the present disclosure, also in the red sub pixel SPR and the green sub pixel SPG having a relatively small size, the light extraction efficiency is improved to improve the front luminance.

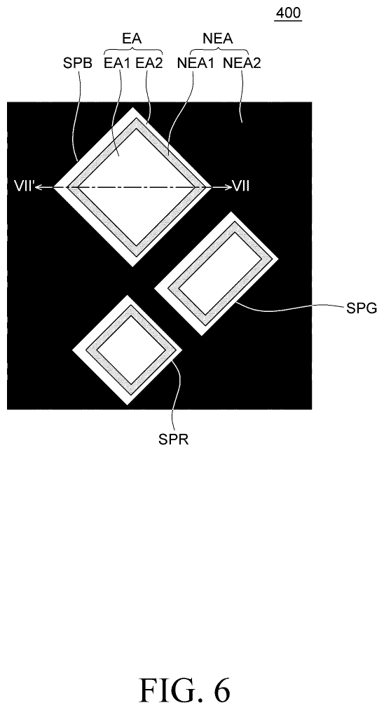

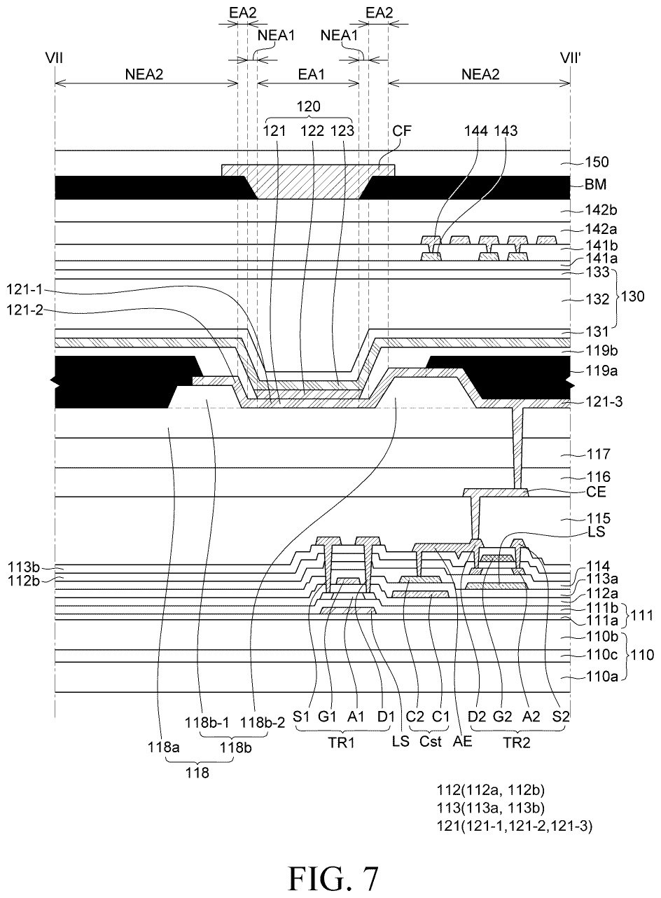

FIG. 6 is an enlarged plan view of the same area as FIG. 2B of a display device according to still another example embodiment of the present disclosure. For example, FIG. 6 is an enlarged view of a pixel disposed in an edge portion of the active area AA. FIG. 7 is a cross-sectional view taken along a line VII-VII′ of FIG. 6. The only difference or a difference between a display device 400 of FIGS. 6 and 7 and the display device 100 of FIGS. 1 to 3B is a structure of a blue sub pixel SPB in the edge portion of the active area AA, but other configurations are substantially the same, so that a redundant description will be omitted or may be briefly provided. FIG. 7 illustrates a cross-sectional view of a red sub pixel SPR disposed in an edge portion of the active area AA and cross-sectional views of a green sub pixel SPG and a blue sub pixel SPB are also the same as the cross-sectional view of the red sub pixel SPR.

Referring to FIG. 6, in the sub pixels disposed in the edge portion of the active area AA, i.e. in the red sub pixel SPR, the green sub pixel SPG and the blue sub pixel SPB, the width of the second emission area EA2 can be asymmetric. For example, parts of the second emission area EA2 which are opposite to each other with respect to a virtual line passing through a center of each sub pixel and parallel to any one of four sides of the sub pixel can have different widths. Referring to FIG. 7, a width of the second electrode part 121-2 of the first electrode 121 can be asymmetric in the sub pixel disposed in the edge portion of the active area AA.

Specifically, in the red sub pixel SPR and the green sub pixel SPG disposed in the edge portion of the active area AA, a width of a part of the second electrode part 121-2 of the first electrode 121 which is adjacent to the non-active area NA is larger than a width of a part of the second electrode part 121-2 of the first electrode 121 which is adjacent to the center portion of the active area AA.

Further, in the blue sub pixel SPB disposed in the edge portion of the active area AA, a width of a part of the second electrode part 121-2 of the first electrode 121 which is adjacent to the non-active area NA is larger than a width of a part of the second electrode part 121-2 of the first electrode 121 which is adjacent to the center portion of the active area AA.

For example, referring to FIG. 6, in the sub pixel of a pixel PX disposed in the left edge portion of the active area AA, the left side of the sub pixel is adjacent to the non-active area NA and the right side of the sub pixel is adjacent to the center portion of the active area AA. Therefore, in the red sub pixel SPR, the green sub pixel SPG, and the blue sub pixel SPB disposed in the left edge portion of the active area AA, a width of a part of the second electrode part 121-2 of the first electrode 121 disposed in the left side is larger than a width of a part of the second electrode part 121-2 of the first electrode 121 located in the right side.

Referring to FIG. 7, in the sub pixel disposed in the edge portion of the active area AA, the protrusion portion 118b has an asymmetric structure. For example, widths of the protrusion portions 118b disposed on both sides of the emission layer 122 with respect to the emission layer 122 can be different from each other.

For example, a part of the protrusion portion 118b disposed in each sub pixel disposed in the edge portion of the active area AA, which is adjacent to the center portion of the active area AA, is referred to as a first protrusion part 118b-1 and a part adjacent to the non-active area NA is referred to as a second protrusion part 118b-2. At this time, the width of the second protrusion part 118b-2 is larger than the width of the first protrusion part 118b-1. For example, a left side of FIG. 7 is a portion adjacent to a center portion of the active area AA and a right side is a portion adjacent to the non-active area NA so that a width of the second protrusion part 118b-2 disposed on the right side on the base portion 118a is larger than a width of the first protrusion part 118b-1 disposed on the left side. For example, the second protrusion part 118b-2 of the protrusion portion 118b has a larger horizontal width and a larger vertical height than those of the first protrusion part 118b-1 of the protrusion portion 118b, but is not limited thereto. For another example, the second protrusion part 118b-2 may have a length longer than that of the first protrusion part 118b-1 so as to define an asymmetric structure of the protrusion portion 118b.

The protrusion portion 118b is formed to have an asymmetric structure in the edge portion of the active area AA so that the first electrode 121 disposed on the protrusion portion 118b also has an asymmetric structure. For example, a width of a part of the first electrode 121 disposed on the second protrusion part 118b-1 which is a part of the protrusion portion 118b adjacent to the non-active area NA is implemented to be larger than a width of a part of the first electrode 121 disposed on the first protrusion part 118b-1 which is a part of the protrusion portion 118b adjacent to the center portion of the active area AA. Therefore, in the area adjacent to the non-active area NA, a reflectable area is increased by the first electrode 121 so that light is more effectively reflected to allow light which is directed to the non-active area NA to be directed to the active area AA.

In the display device 400 according to still another example embodiment of the present disclosure, the light extraction efficiency of the light emitting diode 120 can be improved using the fourth planarization layer 118 including the protrusion portion 118b. For example, in the display device 400 according to still another example embodiment of the present disclosure, the fourth planarization layer 118 includes the base portion 118a and the protrusion portion 118b protruding from the base portion 118a and the first electrode 121 of the light emitting diode 120 is disposed so as to enclose the side surface of the protrusion portion 118b. Light directed to the side surface, among light emitted from the emission layer 122, is reflected by the first electrode 121 disposed on the protrusion portion 118b to be incident at a critical angle or smaller so that the light is extracted toward the front without being trapped in the display device 400 by the total reflection. Therefore, the light extraction efficiency is improved.

Further, in the display device 400 according to still another example embodiment of the present disclosure, the first bank 119a includes a black material. Therefore, the color mixture between adjacent sub pixels is suppressed to improve the reflective visibility. Further, the second electrode part 121-2 of the first electrode 121 disposed on the side surface of the protrusion portion 118b is exposed so that light directed to the side surface is not absorbed by the first bank 119a, but is extracted by the second electrode part 121-2 of the first electrode 121.

Therefore, in the display device 400 according to still another example embodiment of the present disclosure, the width of the second electrode part 121-2 of the first electrode in the red sub pixel SPR and the green sub pixel SPG is adjusted while maintaining the largest size of the blue sub pixel SPB. By doing this, the reflection efficiency of the red sub pixel SPR and the green sub pixel SPG can be improved. For example, the first electrodes 121 disposed in the red sub pixel SPR and the green sub pixel SPG disposed in the edge portion of the active area AA which is adjacent to the non-active area NA can have an asymmetric structure. Specifically, a width of the second electrode part 121-2 of the first electrode 121 exposed by the first bank 119a and the emission layer 122 can be asymmetrically formed. For example, the width of the part of the second electrode part 121-2 of the first electrode 121 which is adjacent to the non-active area NA is formed to be larger than the width of the part of the second electrode part 121-2 of the first electrode 121 which is adjacent to the center portion of the active area AA. For example, the first electrode 121 is disposed so as to enclose the protrusion portion 118b of the fourth planarization layer 118 so that the size of the protrusion portion 118b is asymmetrically formed to implement the width of the second electrode part 121-2 of the first electrode 121 disposed on the side surface of the protrusion portion 142 asymmetrically. For example, the width of the second protrusion part 118b-2 of the protrusion portion 118b which is adjacent to the non-active area NA is formed to be larger than the width of the first protrusion part 118b-1 of the protrusion portion 118b which is adjacent to the center portion of the active area AA by the half-tone process. A width of the part of the second electrode part 121-2 of the first electrode 121 which is disposed on the second protrusion part 118b-2 of the protrusion portion 118b can be implemented to be larger than a width of the part of the second electrode part 121-2 of the first electrode 121 which is disposed on the first protrusion part 118b-1 of the protrusion portion 118b. The width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA. In the area adjacent to the non-active area NA, a reflectable area is increased by the first electrode 121 so that light is more effectively reflected to allow light which is directed to the non-active area NA to be directed to the active area AA. Therefore, in the red sub pixel SPR and the green sub pixel SPG disposed in the edge portion of the active area AA, in a part adjacent to the non-active area NA, a reflectable area is increased by the second electrode part 121-2 of the first electrode 121 so that light directed to the non-active area NA is more effectively reflected to the active area AA. For example, in the display device 400 according to still another example embodiment of the present disclosure, also in the red sub pixel SPR and the green sub pixel SPG having a relatively small size, the light extraction efficiency is improved to improve the front luminance.

Specifically, in the display device 400 according to still another example embodiment of the present disclosure, the structure as described above is applied to the blue sub pixel SPB in the edge portion of the active area AA. For example, also in the blue sub pixel SPB in the edge portion of the active area AA, the size of the protrusion portion 118b is asymmetrically formed to implement the width of the second electrode part 121-2 of the first electrode 121 disposed on the side surface of the protrusion portion 118b asymmetrically. For example, like the red sub pixel SPR and the green sub pixel in the edge portion of the active area AA, also in the blue sub pixel SPB, the width of the second protrusion part 118b-2 which is a part of the protrusion portion 118b adjacent to the non-active area NA is formed to be larger than the width of the first protrusion part 118b-2 of the protrusion portion 118b adjacent to the center portion of the active area AA. Therefore, a width of the part of the second electrode part 121-2 of the first electrode 121 which is disposed on the second protrusion part 118b-2 of the protrusion portion 118b can be implemented to be larger than a width of a part of the second electrode part 121-2 of the first electrode 121 which is disposed on the first protrusion part 118b-1 of the protrusion portion 118b. Accordingly, the width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA. Also in the blue sub pixel SPB disposed in the edge portion of the active area AA, in a part adjacent to the non-active area NA, the reflectable area is increased by the second electrode part 121-2 of the first electrode 121 so that light directed to the non-active area NA can be more effectively reflected to be directed to the active area AA. Therefore, the blue sub pixel SPB also improves the light extraction efficiency to improve the front luminance.

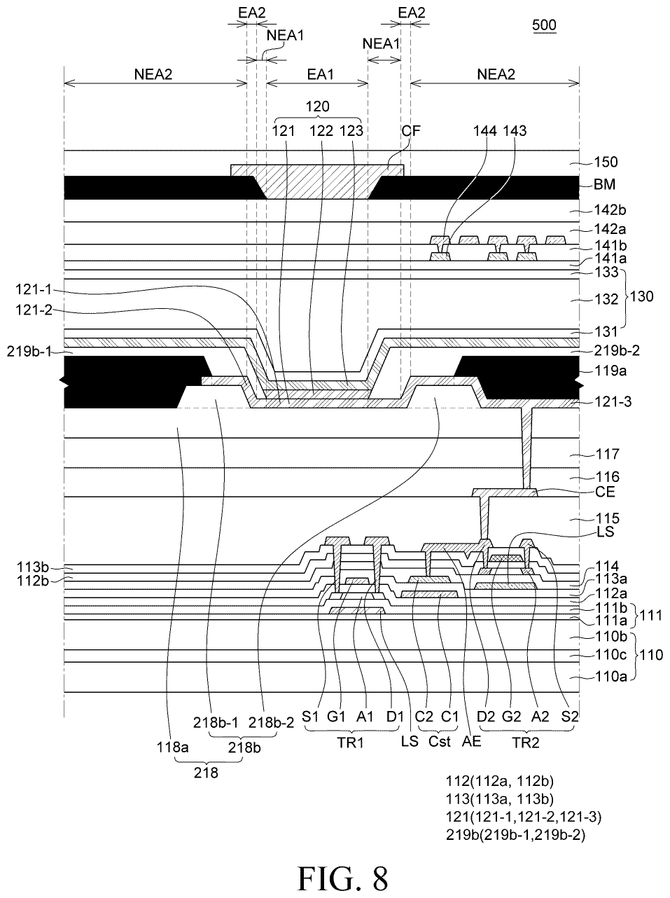

FIG. 8 is a cross-sectional view of the same area as in FIG. 7 of a display device according to still another example embodiment of the present disclosure. For example, FIG. 8 is a cross-sectional view of a red sub pixel SPR, a green sub pixel SPG, and a blue sub pixel SPB disposed in the edge portion of the active area AA. The only difference or a difference between a display device 500 of FIG. 8 and the display device 400 of FIGS. 6 and 7 is a fourth planarization layer 218 and a second bank 219b, but the other configurations are substantially the same, so that a redundant description will be omitted or may be briefly provided.

Referring to FIG. 8, the protrusion portion 218b can have a symmetric structure not only in the red sub pixel SPR, the green sub pixel SPG, and the blue sub pixel SPB in the center portion of the active area AA, but also in the red sub pixel SPR, the green sub pixel SPG, and the blue sub pixel SPB in the edge portion of the active area AA. For example, a width of the second protrusion part 218b-2 of the protrusion portion 218b which is adjacent to the non-active area NA can be equal to the width of the first protrusion part 218b-1 of the protrusion portion 218b which is adjacent to the center portion of the active area AA. For example, in the center portion of the active area and the edge portion of the active area AA, the protrusion portion has the same structure so that the width of the protrusion portion 218b is the same regardless of the direction.

In contrast, the second bank 219b can have an asymmetric structure in the red sub pixel SPR, the green sub pixel SPG, and the blue sub pixel SPB disposed in the edge portion of the active area AA. For example, a part of the second bank 219b disposed in each sub pixel disposed in the edge portion of the active area AA, which is adjacent to the center portion of the active area AA, is referred to as a first bank part 219b-1 and a part of the second bank 219b adjacent to the non-active area NA is referred to as a second bank part 219b-2. At this time, in the red sub pixel SPR, the green sub pixel SPG, and the blue sub pixel SPB disposed in the edge portion of the first active area AA, the width of the second bank part 219b-2 of the second bank 219 is larger than the width of the first bank part 219b-1 of the second bank 219. For example, a left side of FIG. 8 is a portion adjacent to a center portion of the active area AA and a right side is a portion adjacent to the non-active area NA so that a width of the second bank part 219b-2 of the second bank 219 disposed on the right side is larger than a width of the first bank part 219b-1 of the second bank 219 disposed on the left side.

The second bank 219b can have an asymmetric structure in the red sub pixel SPR, the green sub pixel SPG, and the blue sub pixel SPB disposed in the edge of the active area AA so that the first electrode 121 also has an asymmetric structure. For example, the second bank part 219b-2 of the second bank 219b has a width larger than the first bank part 219b-1 of the second bank 219b so that an area of the base portion 118a covered by the second bank part 219b-2 of the second bank 219b but not by the protrusion portion 218b and the first bank 119a can be larger than an area of the base portion 118a covered by the first bank part 219b-1 of the second bank 219b but not by the protrusion portion 218b and the first bank 119a. The shortest distance between the emission layer 122 disposed on the base portion 118a and the second protrusion part 218b-2 of the protrusion portion 218b is longer than the shortest distance between the emission layer 122 and the first protrusion part 218b-1 of the protrusion portion 218b. The part of the second electrode part 121-2 of the first electrode 121 which is adjacent to the non-active area NA is disposed on the base portion 118a and the protrusion portion 218b wider than the part of the second electrode part 121-2 of the first electrode 121 which is adjacent to the center portion of the active area AA.

Therefore, the width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA.

In area adjacent to the non-active area NA, a reflectable area is increased by the first electrode 121 so that light is more effectively reflected to allow light which is directed to the non-active area NA to be directed to the active area AA.

In the display device 500 according to still another example embodiment of the present disclosure, the light extraction efficiency of the light emitting diode 120 can be improved using the fourth planarization layer 218 including the protrusion portion 218b. For example, in the display device 500 according to still another example embodiment of the present disclosure, the fourth planarization layer 218 includes the base portion 118a and the protrusion portion 218b protruding from the base portion 118a and the first electrode 121 of the light emitting diode 120 is disposed so as to enclose the side surface of the protrusion portion 218b. Light directed to the side surface, among light emitted from the emission layer 122, is reflected by the first electrode 121 disposed on the protrusion portion 218b to be incident at a critical angle or smaller so that the light is extracted toward the front without being trapped in the display device 500 by the total reflection. Therefore, the light extraction efficiency is improved.

In the display device 500 according to still another example embodiment of the present disclosure, the first bank 119a includes a black material. Therefore, the color mixture between adjacent sub pixels is suppressed to improve the reflective visibility. Further, the second electrode part 121-2 of the first electrode 121 disposed on the side surface of the protrusion portion 218b is exposed so that light directed to the side surface is not absorbed by the first bank 119a, but is extracted by the second electrode part 121-2 of the first electrode 121.

Therefore, in the display device 500 according to still another example embodiment of the present disclosure, the width of the second electrode part 121-2 of the first electrode in the red sub pixel SPR and the green sub pixel SPG is adjusted while maintaining the largest size of the blue sub pixel SPB. By doing this, the reflection efficiency of the red sub pixel SPR and the green sub pixel SPG can be improved. For example, the first electrodes 121 disposed in the red sub pixel SPR and the green sub pixel SPG disposed in the edge portion of the active area AA which is adjacent to the non-active area NA can have an asymmetric structure. Specifically, a width of the second electrode part 121-2 of the first electrode 121 exposed by the first bank 119a and the emission layer 122 can be asymmetrically formed. For example, the width of the part of the second electrode part 121-2 of the first electrode 121 which is adjacent to the non-active area NA is formed to be larger than the width of the part of the second electrode part 121-2 of the first electrode 121 which is adjacent to the center portion of the active area AA. For example, the size of the second bank 219b is asymmetrically formed to implement the width of the second electrode part 121-2 of the first electrode 121 asymmetrically. For example, the width of the second bank part 219b-2 of the second bank 219b which is adjacent to the non-active area NA can be formed to be larger than the width of the first bank part 219b-1 of the second bank 219b which is adjacent to a center portion of the active area AA. The area of the base portion 118a which is covered by the second bank part 219b-2 of the second bank 219b but not by the protrusion portion 218b and the first bank 119a is also larger than the area of the base portion 118a covered by the first bank part 219b-1 of the second bank 219b but not by the protrusion portion 218b and the first bank 119a. The shortest distance between the emission layer 122 disposed on the base portion 118a and the second protrusion part 218b-2 of the protrusion portion 218b is longer than the shortest distance between the emission layer 122 and the first protrusion part 218b-1 of the protrusion portion 218b. The part of the second electrode part 121-2 of the first electrode 121 which is adjacent to the non-active area NA is disposed on top surfaces of the base portion 118a and the protrusion portion 218b wider than the part of the second electrode part 121-2 of the first electrode 121 which is adjacent to the center portion of the active area AA. The width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA. In the area adjacent to the non-active area NA, a reflectable area is increased by the first electrode 121 so that light is more effectively reflected to allow light which is directed to the non-active area NA to be directed to the active area AA. Therefore, in the red sub pixel SPR and the green sub pixel SPG disposed in the edge portion of the active area AA, in a part adjacent to the non-active area NA, a reflectable area is increased by the second electrode part 121-2 of the first electrode 121 so that light directed to the non-active area NA is more effectively reflected to the active area AA. For example, in the display device 500 according to still another example embodiment of the present disclosure, also in the red sub pixel SPR and the green sub pixel SPG having a relatively small size, the light extraction efficiency is improved to improve the front luminance.

Specifically, in the display device 500 according to still another example embodiment of the present disclosure, the structure as described above is applied to the blue sub pixel SPB in the edge portion of the active area AA. For example, also in the blue sub pixel SPB in the edge portion of the active area AA, the size of the second bank 219b is asymmetrically formed to implement the width of the second electrode part 121-2 of the first electrode 121 asymmetrically. For example, like the red sub pixel SPR and the green sub pixel in the edge portion of the active area AA, also in the blue sub pixel SPB, the width of the second bank part 219b-2 which is a part of the second bank 219b adjacent to the non-active area NA is formed to be larger than the width of the first bank part 219b-1 of the second bank 219b adjacent to the center portion of the active area AA. The area of the base portion 118a which is covered by the second bank part 219b-2 of the second bank 219b but not by the protrusion portion 218b and the first bank 119a is also larger than the area of the base portion 118a covered by the first bank part 219b-1 of the second bank 219b but not by the protrusion portion 218b and the first bank 119a. Therefore, the shortest distance between the emission layer 122 disposed on the base portion 118a and the second protrusion part 218b-2 of the protrusion portion 218b is longer than the shortest distance between the emission layer 122 and the first protrusion part 218b-1 of the protrusion portion 218b. The part of the second electrode part 121-2 of the first electrode 121 which is adjacent to the non-active area NA is disposed on top surfaces of the base portion 118a and the protrusion portion 218b wider than the part of the second electrode part 121-2 of the first electrode 121 which is adjacent to the center portion of the active area AA. The width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA. Also in the blue sub pixel SPB disposed in the edge portion of the active area AA, in a part adjacent to the non-active area NA, the reflectable area is increased by the second electrode part 121-2 of the first electrode 121 so that light directed to the non-active area NA can be more effectively reflected. Therefore, the blue sub pixel SPB also improves the light extraction efficiency to improve the front luminance.

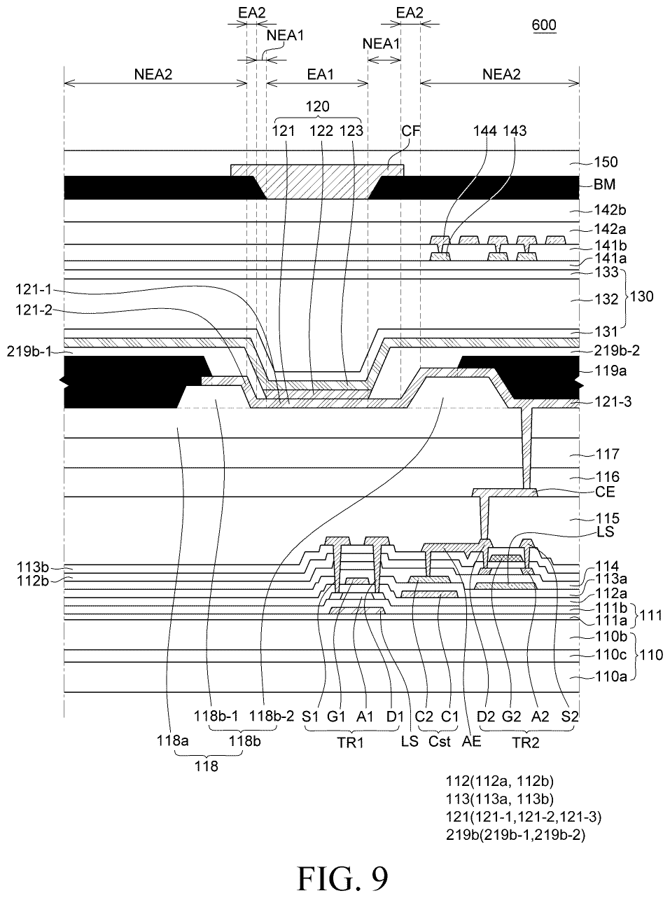

FIG. 9 is a cross-sectional view of the same area as FIG. 7 of a display device according to still another example embodiment of the present disclosure. For example, FIG. 9 is a cross-sectional view of a red sub pixel SPR, a green sub pixel SPG, and a blue sub pixel SPB disposed in the edge portion of the active area AA. The only difference or a difference between a display device 600 of FIG. 9 and the display device 400 of FIGS. 6 and 7 is a second bank 219b, but the other configurations are substantially the same, so that a redundant description will be omitted or may be briefly provided.

Referring to FIG. 9, the protrusion portion 118b is formed to have an asymmetric structure in the edge portion of the active area AA so that the first electrode 121 disposed on the protrusion portion 118b also has an asymmetric structure. For example, a width of a part the first electrode 121 disposed on the second protrusion part 118b-1 which is a part of the protrusion portion 118b adjacent to the non-active area NA is implemented to be larger than a width of a part of the first electrode 121 disposed on the first protrusion part 118b-1 which is a part of the protrusion portion 118b adjacent to the center portion of the active area AA. Therefore, in the area adjacent to the non-active area NA, a reflectable area is increased by the first electrode 121 so that light is more effectively reflected to allow light which is directed to the non-active area NA to be directed to the active area AA.

In the meantime, the second bank 219b is also formed to have an asymmetric structure in the edge portion of the active area so that the first electrode 121 also has an asymmetric structure. For example, the second bank part 219b-2 of the second bank 219b has a width larger than the first bank part 219b-1 of the second bank 219b so that an area of the base portion 118a covered by the second bank part 219b-2 of the second bank 219b but not by the protrusion portion 118b and the first bank 119a can be larger than an area of the base portion 118a covered by the first bank part 219b-1 of the second bank 219b but not by the protrusion portion 118b and the first bank 119a. The shortest distance between the emission layer 122 disposed on the base portion 118a and the second protrusion part 118b-2 of the protrusion portion 118b is longer than the shortest distance between the emission layer 122 and the first protrusion part 118b-1 of the protrusion portion 118b. Therefore, the part of the second electrode part 121-2 of the first electrode 121 which is adjacent to the non-active area NA is disposed on the base portion 118a and the protrusion portion 118b wider than the part of the second electrode part 121-2 of the first electrode 121 which is adjacent to the center portion of the active area AA.

The width of the part of the second part 121-2 of the first electrode 121 which is adjacent to the non-active area NA is implemented to be larger than the width of the part of the second electrode part 121-2 of the first electrode 121 which is adjacent to the center portion of the active area AA.

Therefore, in the area adjacent to the non-active area NA, a reflectable area is increased by the first electrode 121 so that light is more effectively reflected to allow light which is directed to the non-active area NA to be directed to the active area AA.

In the display device 600 according to still another example embodiment of the present disclosure, the light extraction efficiency of the light emitting diode 120 can be improved using the fourth planarization layer 118 including the protrusion portion 118b. For example, in the display device 600 according to still another example embodiment of the present disclosure, the fourth planarization layer 118 includes the base portion 118a and the protrusion portion 118b protruding from the base portion 118a and the first electrode 121 of the light emitting diode 120 is disposed so as to enclose the side surface of the protrusion portion 118b. Light directed to the side surface, among light emitted from the emission layer 122, is reflected by the first electrode 121 disposed on the protrusion portion 118b to be incident at a critical angle or smaller so that the light is extracted toward the front without being trapped in the display device 600 by the total reflection. Therefore, the light extraction efficiency is improved.

Further, in the display device 600 according to still another example embodiment of the present disclosure, the first bank 119a includes a black material. Therefore, the color mixture between adjacent sub pixels is suppressed to improve the reflective visibility. Further, the second electrode part 121-2 of the first electrode 121 disposed on the side surface of the protrusion portion 118b is exposed so that light directed to the side surface is not absorbed by the first bank 119a, but is extracted by the second electrode part 121-2 of the first electrode 121.

Therefore, in the display device 600 according to still another example embodiment of the present disclosure, the width of the second electrode part 121-2 of the first electrode 121 in the red sub pixel SPR and the green sub pixel SPG is adjusted while maintaining the largest size of the blue sub pixel SPB. By doing this, the reflection efficiency of the red sub pixel SPR and the green sub pixel SPG can be improved. For example, the first electrode 121 disposed in the red sub pixel SPR and the green sub pixel SPG disposed in the edge portion of the active area AA which is adjacent to the non-active area NA can have an asymmetric structure. Specifically, a width of the second electrode part 121-2 of the first electrode 121 exposed by the first bank 119a and the emission layer 122 can be asymmetrically formed. For example, the width of the part of the second electrode part 121-2 of the first electrode 121 which is adjacent to the non-active area NA is formed to be larger than the width of the part of the second electrode part 121-2 of the first electrode 121 which is adjacent to the center portion of the active area AA. For example, the first electrode 121 is disposed so as to enclose the protrusion portion 118b of the fourth planarization layer 118 so that the size of the protrusion portion 118b is asymmetrically formed to implement the width of the second electrode part 121-2 of the first electrode 121 disposed on the side surface of the protrusion portion 118b asymmetrically. For example, the width of the second protrusion part 118b-2 of the protrusion portion 118b which is adjacent to the non-active area NA is formed to be larger than the width of the first protrusion part 118b-1 of the protrusion portion 118b which is adjacent to the center portion of the active area AA by the half-tone process. Therefore, a width of the part of the second electrode part 121-2 of the first electrode 121 which is disposed on the second protrusion part 118b-2 of the protrusion portion 118b can be implemented to be larger than a width of a part of the second electrode part 121-2 of the first electrode 121 which is disposed on the first protrusion part 118b-1 of the protrusion portion 118b.

Further, in the display device 600 according to still another example embodiment of the present disclosure, the size of the second bank 219b is also asymmetrically formed to implement the width of the second electrode part 121-2 of the first electrode 121 asymmetrically. For example, the width of the second bank part 219b-2 of the second bank 219b which is adjacent to the non-active area NA can be formed to be larger than the width of the first bank part 219b-1 of the second bank 219b which is adjacent to the center portion of the active area AA. An area of the base portion 118a covered by the second bank part 219b-2 of the second bank 219 but not by the protrusion portion 118b and the first bank 119a can be larger than an area of the base portion 118a covered by the first bank part 219b-1 of the second bank 219 but not by the protrusion portion 118b and the first bank 119a. The shortest distance between the emission layer 122 disposed on the base portion 118a and the second protrusion part 118b-2 of the protrusion portion 118b is longer than the shortest distance between the emission layer 122 and the first protrusion part 118b-1 of the protrusion portion 118b. Therefore, the part of the second electrode part 121-2 of the first electrode 121 which is adjacent to the non-active area NA is disposed on top surfaces of the base portion 118a and the protrusion portion 118b wider than the part of the second electrode part 121-2 of the first electrode 121 which is adjacent to the center portion of the active area AA. The width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA. In area adjacent to the non-active area NA, a reflectable area is increased by the first electrode 121 so that light is more effectively reflected to allow light which is directed to the non-active area NA to be directed to the active area AA. Therefore, in the red sub pixel SPR and the green sub pixel SPG disposed in the edge portion of the active area AA, in a part adjacent to the non-active area NA, a reflectable area is increased by the second electrode part 121-2 of the first electrode 121 so that light directed to the non-active area NA is more effectively reflected to the active area AA. For example, in the display device 600 according to still another example embodiment of the present disclosure, also in the red sub pixel SPR and the green sub pixel SPG having a relatively small size, the light extraction efficiency is improved to improve the front luminance.

Specifically, in the display device 600 according to still another example embodiment of the present disclosure, the structure as described above is applied to the blue sub pixel SPB in the edge portion of the active area AA. For example, also in the blue sub pixel SPB in the edge portion of the active area AA, the size of the protrusion portion 118b of the fourth planarization layer 118 and the second bank 219b are asymmetrically formed to implement the width of the second electrode part 121-2 of the first electrode 121 disposed on the side surface of the protrusion portion 118b asymmetrically. For example, like the red sub pixel SPR and the green sub pixel SPG in the edge portion of the active area, also in the blue sub pixel SPB, the width of the second protrusion part 118b-2 which is a part of the protrusion portion 118b adjacent to the non-active area NA is formed to be larger than the width of the first protrusion part 118b-2 which is a part of the protrusion portion 118b adjacent to the center portion of the active area AA. For example, the width of the second bank part 219b-2 of the second bank 219b which is adjacent to the non-active area NA can be formed to be larger than the width of the first bank part 219b-1 of the second bank 219b which is adjacent to the center portion of the active area AA. Therefore, a width of the part of the second electrode part 121-2 of the first electrode 121 which is disposed on the second protrusion part 118b-2 of the protrusion portion 118b can be implemented to be larger than a width of a part of the second electrode part 121-2 of the first electrode 121 which is disposed on the first protrusion part 118b-1 of the protrusion portion 118b. Further, the part of the second electrode part 121-2 of the first electrode 121 which is adjacent to the non-active area NA is disposed on top surfaces of the base portion 118a and the protrusion portion 118b wider than the part of the second electrode part 121-2 of the first electrode 121 which is adjacent to the center portion of the active area AA. The width of the part of the second electrode part 121-2 of the first electrode 121 which is adjacent to the non-active area NA is implemented to be larger than the width of the part of the second electrode part 121-2 of the first electrode 121 which is adjacent to the center portion of the active area AA. Also in the blue sub pixel SPB disposed in the edge portion of the active area AA, in a part adjacent to the non-active area NA, a reflectable area is increased by the second electrode part 121-2 of the first electrode 121 so that light directed to the non-active area NA is more effectively reflected to the active area AA. Therefore, the blue sub pixel SPB also improves the light extraction efficiency to improve the front luminance.

The example embodiments of the present disclosure can also be described as follows:

A display device according to one or more embodiments of the present disclosure can comprise a substrate defining an active area and a non-active area extending from the active area, wherein a plurality of sub pixels can be disposed in the active area; a planarization layer disposed on the substrate; and a light emitting diode disposed on the planarization layer in each of the plurality of sub pixels, the light emitting diode including a first electrode, an emission layer, and a second electrode which can be sequentially laminated. The planarization layer can include a base portion and a protrusion portion protruding from the base portion, and the first electrode can be disposed on the base portion to enclose a side surface of the protrusion portion.

According to one or more embodiments of the present disclosure, the display device can further comprise a first bank disposed on the planarization layer and the first electrode, wherein the first bank can be disposed between the plurality of sub pixels and includes a black material; and a second bank disposed on the first bank and the first electrode and includes a transparent material.

According to one or more embodiments of the present disclosure, the first electrode can include a first electrode part, a second electrode part and a third electrode part, wherein the first electrode part can be in contact with the emission layer, the second electrode part can be spaced apart from and exposed by the emission layer and the first bank, and the third electrode part can be spaced apart from the emission layer and covered by the first bank. A part of the second electrode part can be disposed on the side surface of the protrusion portion.

According to one or more embodiments of the present disclosure, the plurality of sub pixels can comprise a first sub pixel, a second sub pixel and a third sub pixel which can form one pixel and emit light with different colors from each other.

According to one or more embodiments of the present disclosure, the protrusion portion can include a first protrusion part which is adjacent to the center portion of the active area and a second protrusion part which is adjacent to the non-active area, and the second electrode part can be disposed on the first protrusion part and the second protrusion part.

According to one or more embodiments of the present disclosure, for the light emitting diode in at least one of the first sub pixel, the second sub pixel and the third sub pixel of one pixel disposed in an edge portion of the active area, a width of a part of the second electrode part which is adjacent to the non-active area can be larger than a width of a part of the second electrode part which is adjacent to a center portion of the active area.

According to one or more embodiments of the present disclosure, the protrusion portion can be asymmetrically formed so that a width of the second protrusion part can be larger than a width of the first protrusion part.

According to one or more embodiments of the present disclosure, a width of a part of the second electrode part which is disposed on the second protrusion part can be larger than a width of a part of the second electrode part which is disposed on the first protrusion part.

According to one or more embodiments of the present disclosure, a width of a side surface of the second protrusion part can be larger than a width of a side surface of the first protrusion part.

According to one or more embodiments of the present disclosure, a width of a part of the second electrode part disposed on the side surface of the second protrusion part can be larger than a width of a part of the second electrode part disposed on the side surface of the first protrusion part.

According to one or more embodiments of the present disclosure, the second protrusion part can have a larger horizontal width and a larger vertical width than those of the first protrusion part.

According to one or more embodiments of the present disclosure, the protrusion portion can be symmetrically formed so that a width of the second protrusion part can be equal to a width of the first protrusion part.

According to one or more embodiments of the present disclosure, the second bank can cover the second electrode part and the third electrode part and include a first bank part which is adjacent to the center portion of the active area and a second bank part which is adjacent to the non-active area, and the width of the second bank part can be larger than the width of the first bank part.

According to one or more embodiments of the present disclosure, an area of the base portion covered by the second bank part but not by the protrusion portion and the first bank can be larger than an area of the base portion covered by the first bank part but not by the protrusion portion and the first bank.

According to one or more embodiments of the present disclosure, the shortest distance between the emission layer disposed on the base portion and the second protrusion part can be longer than the shortest distance between the emission layer and the first protrusion part.

According to one or more embodiments of the present disclosure, the second bank part can extend onto the base portion more than the first bank part so that the second bank part can have the same height as the first bank part, but have a larger horizontal width.

According to one or more embodiments of the present disclosure, the second bank part can have a slope gentler than the first bank part.

According to one or more embodiments of the present disclosure, the size of the third sub pixel can be larger than the sizes of the first sub pixel and the second sub pix.

According to one or more embodiments of the present disclosure, the first sub pixel can emit red light, the second sub pixel can emit green light and the third sub pixel can emit blue light.

According to one or more embodiments of the present disclosure, the display device can further comprises a thin film transistor for driving the light emitting diode. The thin film transistor can be disposed on the substrate and covered by the planarization layer.

According to one or more embodiments of the present disclosure, each of the plurality of sub pixels may include a plurality of emission areas and a plurality of non-emission areas.

According to one or more embodiments of the present disclosure, the plurality of emission areas may include a first emission area and a second emission area which encloses the first emission area, and the plurality of non-emission areas may include a first non-emission area disposed between the first emission area and the second emission area, and a second non-emission area which encloses the second emission area, wherein the first non-emission area may be disposed closer to the emission layer than the second non-emission area.

According to one or more embodiments of the present disclosure, the second protrusion part may have a length longer than that of the first protrusion part.

Although the example embodiments of the present disclosure have been described in detail with reference to the accompanying drawings, the present disclosure is not limited thereto and can be embodied in many different forms without departing from the technical concept of the present disclosure. The example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device comprising:
a substrate defining an active area and a non-active area extending from the active area, wherein a plurality of sub pixels are disposed in the active area;
a planarization layer disposed on the substrate; and
a light emitting diode disposed on the planarization layer in each of the plurality of sub pixels, the light emitting diode including a first electrode, an emission layer, and a second electrode which are sequentially laminated,
wherein the planarization layer includes a base portion and a protrusion portion protruding from the base portion, and
wherein the first electrode is disposed on the base portion to enclose a side surface of the protrusion portion.

2. The display device according to claim 1, further comprising:
a first bank disposed on the planarization layer and the first electrode, wherein the first bank is disposed between the plurality of sub pixels and includes a black material; and
a second bank disposed on the first bank and the first electrode and including a transparent material.

3. The display device according to claim 2, wherein the first electrode includes a first electrode part, a second electrode part and a third electrode part,
wherein the first electrode part is in contact with the emission layer, the second electrode part is spaced apart from and exposed by the emission layer and the first bank, and the third electrode part is spaced apart from the emission layer and covered by the first bank, and
wherein a part of the second electrode part is disposed on the side surface of the protrusion portion.

4. The display device according to claim 3, wherein the plurality of sub pixels comprise a first sub pixel, a second sub pixel and a third sub pixel which form one pixel and are configured to emit light with different colors from each other.

5. The display device according to claim 4, wherein the protrusion portion of the planarization layer includes a first protrusion part which is adjacent to a center portion of the active area and a second protrusion part which is adjacent to the non-active area, and
wherein the second electrode part is disposed on the first protrusion part and the second protrusion part.

6. The display device according to claim 5, wherein, for the light emitting diode in at least one of the first sub pixel, the second sub pixel and the third sub pixel of one pixel disposed in an edge portion of the active area, a width of a part of the second electrode part which is adjacent to the non-active area is larger than a width of a part of the second electrode part which is adjacent to the center portion of the active area.

7. The display device according to claim 6, wherein the protrusion portion is asymmetrically formed so that a width of the second protrusion part is larger than a width of the first protrusion part.

8. The display device according to claim 7, wherein a width of a part of the second electrode part which is disposed on the second protrusion part is larger than a width of a part of the second electrode part which is disposed on the first protrusion part.

9. The display device according to claim 7, wherein a width of a side surface of the second protrusion part is larger than a width of a side surface of the first protrusion part.

10. The display device according to claim 9, wherein a width of a part of the second electrode part disposed on the side surface of the second protrusion part is larger than a width of a part of the second electrode part disposed on the side surface of the first protrusion part.

11. The display device according to claim 7, wherein the second protrusion part has a larger horizontal width and a larger vertical height than those of the first protrusion part.

12. The display device according to claim 6, wherein the protrusion portion is symmetrically formed so that a width of the second protrusion part is equal to a width of the first protrusion part.

13. The display device according to claim 7, wherein the second bank covers the second electrode part and the third electrode part, and includes a first bank part which is adjacent to the center portion of the active area and a second bank part which is adjacent to the non-active area, and
wherein the width of the second bank part is larger than the width of the first bank part.

14. The display device according to claim 13, wherein an area of the base portion covered by the second bank part but not by the protrusion portion and the first bank is larger than an area of the base portion covered by the first bank part but not by the protrusion portion and the first bank.

15. The display device according to claim 13, wherein a shortest distance between the emission layer disposed on the base portion and the second protrusion part is longer than a shortest distance between the emission layer and the first protrusion part.

16. The display device according to claim 13, wherein the second bank part extends onto the base portion more than the first bank part so that the second bank part has a same height as the first bank part, but has a larger horizontal width.

17. The display device according to claim 16, wherein the second bank part has a slope less than a slope of the first bank part.

18. The display device according to claim 13, wherein a size of the third sub pixel is larger than sizes of the first sub pixel and the second sub pixel.

19. The display device according to claim 13, wherein the first sub pixel is configured to emit red light, the second sub pixel is configured to emit green light, and the third sub pixel is configured to emit blue light.

20. The display device according to claim 1, further comprising:
a thin film transistor for driving the light emitting diode, wherein the thin film transistor is disposed on the substrate and covered by the planarization layer.

21. The display device according to claim 1, wherein each of the plurality of sub pixels includes a plurality of emission areas and a plurality of non-emission areas.

22. The display device according to claim 21, wherein the plurality of emission areas include a first emission area and a second emission area which encloses the first emission area, and the plurality of non-emission areas include a first non-emission area disposed between the first emission area and the second emission area, and a second non-emission area which encloses the second emission area, wherein the first non-emission area is disposed closer to the emission layer than the second non-emission area.

23. The display device according to claim 5, wherein the second protrusion part has a length longer than that of the first protrusion part.
